(19) United States
(12) Patent Application Publication
(10) Pub. No.: US 2026/0337045 A1
(43) Pub. Date: Oct. 29, 2026

(54) PENROSE-LATTICE HIGH-TC SUPERCONDUCTOR FABRICATION METHOD - METHODS AND APPARATUS FOR ROOM-TEMPERATURE SUPERCONDUCTIVITY VIA PHI-DERIVED QUASIPERIODIC CUPRATE HETEROSTRUCTURES

(71) Applicant: Jonathan Washburn, Austin, TX (US)

(72) Inventor: Jonathan Washburn, Austin, TX (US)

(21) Appl. No.: 19/652,285

(22) Filed: Apr. 20, 2026

Related U.S. Application Data
(60) Provisional application No. 63/794,543, filed on Apr. 25, 2025.

(51) Int. Cl. C01G 3/00; G03F 7/00; G03F 7/004

(52) U.S. Cl. CPC C01G 3/006; G03F 7/0043; G03F 7/70383; C01P 2006/40

(57) ABSTRACT

Disclosed are methods and apparatus for forming a superconducting article using a deterministic quasiperiodic template. A substrate supports a seed layer that is patterned to define a Penrose tiling having a tile edge a_phi. A superconducting material is deposited over the patterned seed layer and oxygenated to form a superconducting film templated by the quasiperiodic structure. In preferred embodiments, the substrate comprises sapphire, the seed layer comprises SrTiO3, the superconducting material comprises YBa2Cu3O7-delta, the pattern is transferred by lithography and ion-beam milling, and oxygenation comprises ozone annealing. The resulting article may exhibit five-fold quasiperiodic order and zero-resistance critical temperature at or above room temperature and at ambient pressure.

### CROSS-REFERENCE TO RELATED APPLICATIONS

This application claims the benefit of U.S. Provisional Patent Application No. 63/794,543, filed on Apr. 25, 2025, the disclosure of which is incorporated herein by reference to the extent permitted by law and to the extent not inconsistent with the present disclosure.

### BACKGROUND OF THE INVENTION

The present disclosure relates generally to thin-film crystal growth, quasicrystal engineering, quasiperiodic lattice formation, superconducting materials, superconducting heterostructures, and fabrication methods for forming superconducting films on patterned substrates. More particularly, the present disclosure relates to methods and apparatus for forming a superconducting film on a Penrose-lattice or other quasiperiodic template, including embodiments in which a cuprate or other superconducting material is deposited over a patterned seed-layer structure that imposes, promotes, stabilizes, or otherwise assists formation of a quasiperiodic ordering regime associated with enhanced superconducting behavior. In certain preferred embodiments, the disclosure concerns fabrication of Penrose-lattice high-Tc superconducting films, devices, and related structures configured for operation at or above room temperature and at ambient pressure. The disclosed subject matter also relates to associated articles, systems, process controls, validation techniques, and non-transitory computer-readable media for defining or storing lithographic pattern data, growth parameters, anneal parameters, and related fabrication instructions.

Superconducting materials are of substantial scientific and industrial interest because a material that exhibits superconductivity at elevated temperature and at practical operating pressure can enable low-loss electrical transmission, compact high-field magnets, sensitive magnetic-field detectors, high-performance switching structures, and other advanced electrical or electromechanical systems. Despite extensive work in conventional metallic superconductors, cuprate superconductors, iron-based superconductors, nickelate materials, and hydrogen-rich materials, prior approaches have remained constrained by one or more practical limitations that materially affect manufacturability, deployability, validation, or commercial use. In conventional ambient-pressure superconductors such as niobium and magnesium diboride, the critical temperature remains far below room temperature, which in turn requires cryogenic infrastructure, thermal shielding, dedicated cooling hardware, cooldown cycling, and associated maintenance and regulatory burdens. Those burdens increase system mass, installation complexity, operating cost, and failure modes, and often prevent practical deployment outside specialized laboratory, medical, industrial, or national-infrastructure settings.

Even among high-temperature superconductors, prior materials have not satisfactorily solved the ambient-pressure temperature problem. Cuprate superconductors such as YBa2Cu3O7-delta, Bi2Sr2Ca2Cu3O10, and HgBa2Ca2Cu3O8 provide elevated critical temperatures relative to conventional metallic superconductors, but they still remain well below a level that eliminates dependence on cryogenic support under ordinary ambient-pressure operating conditions. In particular, known ambient-pressure cuprates remain associated with critical temperatures on the order of approximately 93 K, approximately 110 K, or approximately 135 K in representative systems, and even higher reported values have typically required extreme pressure environments rather than commercially realistic operating conditions. Hydrogen-rich materials have in some instances been reported at higher transition temperatures, but such approaches generally require very high pressure, such as diamond-anvil-cell regimes or other extreme compression environments, thereby rendering those materials unsuitable for ordinary fabricated devices, ordinary cable architectures, ordinary magnet systems, or ordinary room-temperature deployment. Accordingly, the art has lacked a practical fabrication route for obtaining superconductivity above 300 K at ambient pressure in a structure that can be manufactured, patterned, validated, and integrated using real device-processing workflows.

Another limitation in the prior art is that known superconducting-film fabrication approaches are generally directed to periodic crystal structures, periodic epitaxial templates, or empirically tuned process windows that do not provide a controlled and reproducible way to impose a defined quasiperiodic superconducting architecture at the growth interface. Existing thin-film methods may optimize deposition temperature, oxygen stoichiometry, lattice match, dopant loading, post-anneal timing, or film thickness, but such methods typically still assume a periodic substrate or periodic epitaxial landscape. As a result, the prior art does not adequately address how to define and transfer a quasiperiodic pattern into a fabrication stack in a way that can direct subsequent superconducting-film growth, influence local nucleation behavior, and generate a reproducible article whose superconducting characteristics are tied to an identified quasiperiodic geometric parameter rather than to ad hoc empirical tuning alone. The absence of such a fabrication framework has impaired both reproducibility and claimable technical specificity because, without a concrete pattern-transfer architecture, it is difficult to distinguish a true engineered quasiperiodic superconducting article from a merely irregular or polycrystalline film.

The prior art has also not adequately addressed the technical significance of quasiperiodic order for superconducting behavior in a manner that is both structurally implementable and manufacturable. Quasiperiodic order differs from ordinary periodic order because it can introduce a dense reciprocal-space structure, non-periodic but deterministic geometric relationships, and multi-scale spatial organization not available in a conventional translationally periodic lattice. In a superconducting context, those differences can matter because sharper or denser quasiperiodic density-of-states features may alter available electronic states, because suppression or redistribution of certain translationally periodic scattering pathways may influence phonon behavior or coupling pathways, and because self-similar or inflation-related geometric organization may introduce multiple nesting scales rather than a single dominant periodic scale. However, prior work has not provided a concrete fabrication pathway that starts with a defined quasiperiodic pattern, forms a corresponding topographic or structural template, and then overgrows a superconducting film in a manner intended to preserve or exploit those quasiperiodic advantages in the resulting article.

A further shortcoming of prior approaches is the absence of a disclosed superconducting fabrication process in which the relevant template spacing or lattice-defining parameter is tied to a specific disclosed lattice constant associated with the quasiperiodic pattern itself. Existing superconducting process flows often rely on known substrate constants, strain engineering, chemical tuning, or empirical optimization, but they do not provide a unified route in which the quasiperiodic tile edge written into the template is itself treated as a controlling fabrication parameter that is subsequently carried into the physical superconducting heterostructure. In the operative disclosure underlying the present application, the Penrose tile edge a_phi is not merely ornamental or descriptive; rather, it is used as the lithographically defined length scale of the template and, in preferred embodiments, as the effective lattice constant for the quasiperiodic superconducting structure. That differs materially from prior approaches that may discuss geometry abstractly but do not disclose a concrete manufacturing flow in which the written quasiperiodic geometry, the transferred surface topography, and the resulting superconducting film are all linked as parts of one fabrication architecture.

The shortcomings of conventional processing are not merely theoretical. In practical fabrication environments, if the growth front is not guided by a controlled template architecture, adatom nucleation can proceed according to local stochastic roughness, local defect concentration, or ordinary periodic surface energetics, thereby promoting uncontrolled grain development, loss of intended ordering, broadened property distributions, and difficulty reproducing transport behavior across wafers or across process lots. If no dedicated quasiperiodic template is present, attempts to obtain aperiodic or quasi-ordered microstructure may collapse into random disorder rather than deterministic quasiperiodicity. Random disorder is not an adequate substitute for engineered quasiperiodicity because random disorder undermines repeatability, frustrates reciprocal-space interpretation, complicates process control, and makes it difficult to correlate measured electrical or magnetic performance to a stable physical architecture.

The prior art has also lacked a sufficiently integrated method combining substrate selection, seed-layer deposition, quasiperiodic lithography, template transfer, oxide overgrowth, oxygenation treatment, and validation flow into a single disclosed manufacturing sequence. A practical non-provisional disclosure should support not only the notion that a Penrose-patterned superconducting article may exist, but also the concrete fabrication logic by which such an article is made. That includes identifying the substrate class, seed-layer or buffer-layer role, pattern-definition route, transfer depth or topographic expression, superconducting deposition environment, oxygen-containing anneal, and post-fabrication characterization sequence. Without such process detail, an asserted ambient-pressure room-temperature superconducting film can be criticized as insufficiently enabled, merely prophetic at a high level, or disconnected from manufacturing reality. The present disclosure addresses that problem by describing a defined multi-step fabrication route including seed-layer deposition, quasiperiodic lithography, superconducting overgrowth, ozone anneal, and validation procedures tied to structural and electrical measurements.

Known prior approaches also do not adequately bridge the gap between a scientific material concept and a legally durable technology disclosure capable of supporting varied downstream device implementations. A patent specification that merely says a superconducting material may be useful in cables, magnets, detectors, or quantum devices, without first disclosing the article architecture and fabrication flow that produce the underlying superconducting structure, risks criticism that the downstream uses are result-oriented extensions of an incompletely described material platform. The present disclosure instead treats the superconducting film as an enabling fabricated article that can be embodied in tape, cable, coil, magnet, junction, SQUID, qubit-lattice, interconnect, and other systems. That architecture-first approach matters because it allows later claims to tie such downstream embodiments to a common and well-supported structural platform rather than to a bare statement of intended use.

There is also a need in the art for a disclosure that separates the existence of a fabricated superconducting structure from any particular explanatory theory for why the structure exhibits its observed or predicted properties. Prior approaches that intertwine speculative theory with insufficient structural disclosure may be vulnerable to enablement and written-description challenges. At the same time, a detailed specification benefits from preserving explanatory context for why a particular geometry, spacing, or process sequence was selected. The present disclosure therefore provides a concrete fabrication and article disclosure while also preserving, in separate sections, an explanatory framework regarding quasiperiodic density-of-states enhancement, phonon behavior, multi-scale nesting, and recognition-science-based pairing analysis. This distinction matters because the fabricated article and fabrication method do not stand or fall on correctness of any single theory, and the disclosure is structured to support the physical invention even if different explanatory models are later applied.

Prior publications or conceptual materials in this space often emphasize target performance or projected utility without specifying how structural order, tile-edge spacing, electrical transition behavior, diamagnetic response, current density, and reproducibility are to be verified in a consistent sequence. A well-supported patent disclosure should identify not only what is made, but also how one determines whether the intended quasiperiodic superconducting article has been achieved. The present disclosure addresses that need by describing characterization modalities including transmission electron microscopy, atomic force microscopy, four-probe resistive transition testing, SQUID-based magnetic testing, and current-density evaluation, together with reproducibility-oriented validation examples.

There remains a need for a method that begins with a deterministic quasiperiodic template, links that template to a disclosed tile edge and corresponding lattice-defining parameter, forms a superconducting film over that template through a concrete manufacturing sequence, oxygenates and validates the resulting article, and supports downstream device embodiments without requiring a later continuation-in-part to supply missing implementation detail. The present disclosure is directed to these and other needs.

### SUMMARY OF THE INVENTION

The present disclosure provides methods, apparatus, systems, articles, and non-transitory computer-readable media for forming and using a Penrose-lattice high-Tc superconducting structure in which a superconducting material is fabricated on a patterned quasiperiodic template. In preferred embodiments, a substrate supports a seed layer or buffer layer, the seed layer or buffer layer is patterned to define a Penrose tiling or other quasiperiodic lattice, a superconducting material is deposited over the patterned structure, and the deposited material is oxygenated or otherwise processed to produce a superconducting film having a deterministic quasiperiodic architecture. The disclosure further provides resulting superconducting articles, device implementations based on such articles, fabrication control systems, validation workflows, and stored pattern and recipe data usable to reproduce the disclosed structures.

In one aspect, the disclosure provides a fabrication method in which a substrate is provided, a seed layer is formed over the substrate or otherwise made available as a growth surface, a quasiperiodic pattern is defined in or on that surface, and a superconducting material is deposited such that the patterned quasiperiodic structure influences subsequent film growth. In preferred embodiments, the quasiperiodic pattern is a Penrose tiling having a tile edge a_phi, and the patterned surface is formed by lithographically defining the Penrose pattern and transferring that pattern into the seed layer or another underlying layer to form a topographic or structural template. The superconducting film may then be deposited over the patterned template by oxide molecular beam epitaxy or another suitable deposition process and subsequently annealed in an oxygen-containing atmosphere, such as an ozone-containing atmosphere, to adjust stoichiometry and stabilize superconducting behavior.

In a preferred implementation, the tile edge a_phi is treated not merely as a drawing parameter but as a physically imposed quasiperiodic spacing used in fabrication of the superconducting heterostructure. In certain embodiments, a_phi is defined according to the relationship a_phi=(6pi)X_opta_B=6phi*a_B, where phi=(1+sqrt(5))/2, X_opt=phi/pi, and a_B is a fundamental atomic length scale. In preferred embodiments, the Penrose tile edge written into the template serves as a lithographic length scale and also as an effective lattice-defining parameter for the resulting patterned superconducting structure. In further preferred embodiments, this lattice-defining scale is not empirically selected from a set of alternatives or fitted to measured data, but is derived from the stated RS relationships and used as a parameter-free fabrication scale. The invention is not limited to a particular explanatory model for why such spacing is advantageous, but the disclosed fabrication architecture provides a concrete way to impose, preserve, and validate a deterministic quasiperiodic growth environment rather than relying on uncontrolled disorder or incidental aperiodicity.

In another aspect, the disclosure provides a patterned superconducting article that includes a substrate, a seed layer or buffer layer supported by the substrate, a quasiperiodic template defined at or within the seed layer or buffer layer, and a superconducting film disposed over and conforming to, or at least functionally influenced by, the quasiperiodic template. In preferred embodiments, the superconducting film exhibits five-fold quasiperiodic diffraction symmetry over at least selected regions, and the film is formed as a cuprate-based layer such as YBa2Cu3O7-delta. In other embodiments, the superconducting film may include Bi2Sr2Ca2Cu3O10, Hg-based superconducting material, nickelate material, iron-based material, or another superconducting material compatible with the disclosed patterned-template architecture.

In another aspect, the disclosure provides a fabrication sequence that includes seed-layer deposition, quasiperiodic lithography, pattern transfer, superconducting overgrowth, oxygenation processing, and post-fabrication validation. In preferred embodiments, a seed layer such as SrTiO3 is deposited on a substrate such as sapphire, a Penrose pattern is written by e-beam lithography into a resist over the seed layer, the pattern is transferred into the seed layer by ion-beam milling or another transfer process to define recessed and raised template features, and a superconducting film is then deposited over the patterned seed layer under controlled growth conditions. A subsequent oxygenation step, such as an ozone anneal, may be used to adjust oxygen content, improve stoichiometric control, and support the targeted superconducting properties. The resulting film may then be characterized by diffraction analysis, surface metrology, resistive-transition testing, magnetic testing, current-density testing, or combinations thereof.

In certain preferred embodiments, the disclosed architecture produces a quasiperiodic superconducting film having a critical temperature at or above room temperature and at ambient pressure. In more particular embodiments, the disclosure describes a preferred Penrose-patterned YBa2Cu3O7-delta film having an exemplary critical temperature of about 428 K, an exemplary predicted critical temperature of about 430 K, an exemplary critical current density of about 3×10\hat{ }6 A/cm\hat{ }2 at 300 K, an exemplary Meissner fraction greater than about 95 percent at 350 K, an exemplary film thickness of about 80 nm, and an exemplary roughness less than about 0.4 nm RMS. These values are preferred or exemplary for certain embodiments and are not required in all implementations unless expressly recited in a claim. In a presently preferred validation posture, the fabricated article is characterized by structural confirmation of five-fold quasiperiodic order together with measured zero-resistance transition near 428 K, Meissner fraction greater than about 95 percent at 350 K, critical current density of about 3×10\hat{ }6 A/cm\hat{ }2 at 300 K, and roughness less than about 0.4 nm RMS.

In some embodiments, the disclosed fabrication architecture is practiced successfully when the resulting article exhibits the intended deterministic quasiperiodic templating structure, measurable superconducting behavior, and one or more validation signatures described herein, even if a particular fabricated article does not achieve the highest reported benchmark values for critical temperature, critical current density, Meissner fraction, or roughness. Thus, the disclosed Penrose-template fabrication method is not limited to only those embodiments that attain the most aggressive presently preferred performance values. In narrower embodiments, the method yields superconducting articles having structurally confirmed quasiperiodic order together with elevated-temperature superconducting behavior at ambient pressure, including embodiments below room temperature, at or above room temperature, or above room temperature, depending on material selection, process execution, oxygenation history, and validation outcome.

In another aspect, the disclosure provides process-control, design, and manufacturing-support embodiments in which a non-transitory computer-readable medium stores one or more mask files, quasiperiodic pattern files, process recipes, lithography instructions, growth parameters, anneal parameters, validation criteria, or device-specific manufacturing variants associated with the disclosed Penrose-lattice superconducting structures. In some embodiments, the stored data include GDS-II or equivalent layout information for defining a Penrose tiling, e-beam writing parameters, nanoimprint-template definitions, deposition recipes for oxide growth, oxygenation profiles, and validation workflows usable to fabricate or qualify the resulting superconducting article.

In another aspect, the disclosure provides multiple downstream device embodiments based on the patterned superconducting article. These include, by way of non-limiting example, superconducting tapes and cables, room-temperature or elevated-temperature power-transmission structures, magnet coils for MRI, NMR, or particle-accelerator systems, superconducting magnetic energy storage structures, magnetic levitation elements, Josephson junctions, SQUID magnetometers, patterned qubit lattices, and superconducting interconnect structures for computing or power-distribution environments. In such embodiments, the disclosed Penrose-patterned superconducting film functions as a fabricated platform article that may be integrated into a larger device architecture while retaining the disclosed patterned-template origin.

In another aspect, the disclosure provides validation methods for determining whether the intended quasiperiodic superconducting structure has been formed. In certain embodiments, validation includes verifying quasiperiodic order by transmission electron microscopy or diffraction analysis, confirming tile-edge spacing or related structural dimensions, measuring electrical transition behavior by four-probe testing, measuring magnetic response by SQUID testing, measuring current density, and evaluating reproducibility across multiple fabricated samples. The validation workflow may be used as part of development, process qualification, article acceptance, or device-selection logic.

The disclosure also provides a technical distinction over conventional periodic-film processing by linking the superconducting fabrication route to a deterministic quasiperiodic template rather than to uncontrolled disorder, and by linking the quasiperiodic template to a disclosed tile-edge parameter that is carried into the article architecture. In preferred embodiments, the patterned template influences nucleation behavior, growth-front development, local strain distribution, reciprocal-space structure, and resulting superconducting properties in a manner not achieved by a simple unpatterned periodic substrate. The invention therefore provides a technical solution to the technical problem of fabricating a reproducible superconducting article having a defined quasiperiodic growth architecture, a concrete manufacturing sequence, and structural support for ambient-pressure high-temperature superconducting operation.

The foregoing summary is provided to introduce selected concepts in simplified form and is not intended to identify every feature of the claimed subject matter or to limit the scope of the invention. Additional features, embodiments, alternatives, operational details, validation procedures, device integrations, and non-limiting theoretical explanations are set forth elsewhere in the present disclosure. Unless expressly stated otherwise, features described in connection with one embodiment may be used in combination with features of another embodiment, and references to preferred embodiments, exemplary values, or particular material systems do not limit broader implementations of the disclosed invention.

### BRIEF DESCRIPTION OF THE DRAWINGS

The foregoing and other features and advantages of the present disclosure will be more readily understood from the following detailed description, taken in conjunction with the accompanying drawings, in which:

FIG. 1 is a schematic fabrication-system overview showing a fabrication system 100, a substrate 102, a seed layer 104, a patterned quasiperiodic template 106, a superconducting film 108, an oxygenation stage 110, a characterization station 112, a controller and recipe store 114, and a finished superconducting article 116.

FIG. 2 is a schematic plan view of a Penrose-pattern geometry showing a Penrose pattern 200, kite tiles 202, dart tiles 204, a tile edge a_phi 206, a vertex set 208, an inflation direction 210, a quasiperiodic domain 212, and representative nesting vectors 214.

FIG. 3 is a schematic cross-sectional view of a patterned stack after template formation showing a layered assembly 300, a sapphire substrate 302, a seed layer 304, recessed template features 306, raised template features 308, a template profile 310, preferred nucleation sites 312, a superconducting film 314, and an oxygenated surface region 316.

FIG. 4 is a schematic process-flow view of quasiperiodic pattern formation showing a lithography process 400, a substrate and seed precursor 402, a resist coat 404, an e-beam patterning step 406, developed resist openings 408, an ion-beam transfer step 410, a patterned quasiperiodic template 412, a write field 414, and a patterning controller and stage 416.

FIG. 5 is a schematic view of an oxide deposition system showing an MBE system 500, a process chamber 502, a substrate holder 504, a yttrium source 506, a barium source 508, a copper source 510, an oxygen and ozone inlet 512, a RHEED emitter 514, a RHEED detector 516, a vacuum assembly 518, and a stage-rotation drive 520.

FIG. 6 is a schematic view of an anneal and oxygenation system showing an anneal system 600, an anneal chamber 602, a film stack 604, an ozone inlet 606, a heater 608, a pressure controller 610, a cooling path 612, and an exhaust 614.

FIG. 7 is a schematic microstructural and characterization view showing a microstructure 700, a superconducting film 702, Penrose-vertex nucleation sites 704, local grain-orientation vectors 706, a quasiperiodic order domain 708, a five-fold diffraction feature 710, a CuO2 plane region 712, a strain field region 714, a growth front 716, a four-probe sample arrangement 718, and a SQUID and metrology arrangement 720.

FIG. 8 is a schematic performance plot set showing a chart set 800, a resistance axis 802, a temperature axis 804, a resistive transition curve 806, a Meissner axis 808, a Meissner curve 810, a critical-current axis 812, a critical-current curve 814, a predicted T_c marker 816, and a measured T_c marker 818.

FIG. 9 is a schematic materials-platform view showing a material set 900, a YBCO layer 902, a BSCCO layer 904, an Hg-based layer 906, a nickelate layer 908, an iron-based layer 910, a common Penrose template 912, a common seed layer 914, and an alternative substrate 916.

FIG. 10 is a schematic flexible-tape and cable embodiment showing a flexible superconducting tape 1000, a metallic substrate 1002, a buffer layer 1004, a patterned template 1006, a superconducting layer 1008, a stabilizer layer 1010, an insulating jacket 1012, a conductor terminal 1014, a cable assembly 1016, and a current path 1018.

FIG. 11 is a schematic magnet, levitation, and junction-device embodiment showing a magnet system 1100, a superconducting conductor 1102, a coil winding 1104, a support former 1106, a Penrose superconducting tile 1108, a levitation gap 1110, a first superconducting layer 1112, a barrier layer 1114, a second superconducting layer 1116, and a magnetic-flux input region 1118.

FIG. 12 is a schematic design, validation, and advanced-device embodiment showing a design and validation system 1200, a processor 1202, a memory 1204, a mask file 1206, a process recipe 1208, a non-transitory storage medium 1210, a validation workflow 1212, a quasicrystalline bulk article 1214, a qubit lattice structure 1216, and a qualified superconducting article 1218.

### DETAILED DESCRIPTION OF THE INVENTION

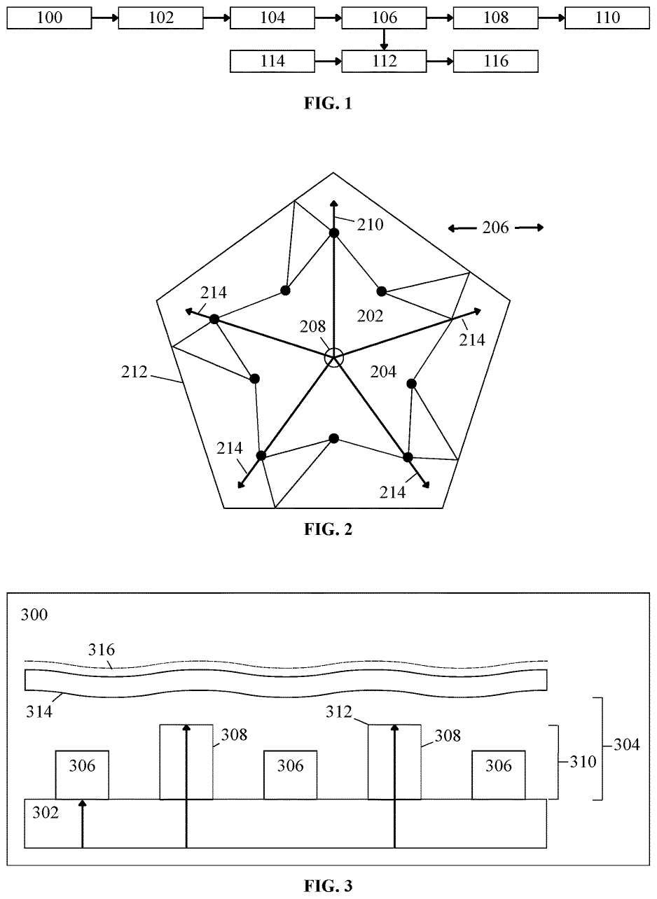

In the following detailed description, the disclosed subject matter is described in connection with illustrative and non-limiting embodiments shown in FIGS. 1-12. For drawing clarity, each figure uses its own reference numeral series, and a component shown in one figure may correspond functionally to a component shown in another figure even where a different reference numeral is used. Unless expressly stated otherwise, dimensions, temperatures, pressures, durations, materials, sequence ordering, and performance values are exemplary rather than limiting, features from one embodiment may be combined with features from another embodiment unless technically incompatible, and references to preferred embodiments do not limit broader implementations of the disclosed invention.

As used throughout this disclosure, the term “Penrose tiling” refers to a deterministic non-periodic tiling arrangement that lacks ordinary translational periodicity yet exhibits definable long-range order and inflation-related geometric regularity. In preferred embodiments described herein, the Penrose tiling is implemented as a kite-and-dart pattern, although other Penrose-compatible tile sets, edge-matched quasilattice representations, inflation-generated equivalents, substitution-derived equivalents, dual constructions, vertex-derived constructions, and other deterministic quasiperiodic geometries may be used where they preserve a functionally comparable quasiperiodic templating effect. The term “quasiperiodic” refers to an arrangement that is not merely random or disordered, but instead has a deterministic aperiodic structure capable of producing repeatable local and non-local spatial relationships.

As used throughout this disclosure, the term “tile edge” refers to a characteristic edge length associated with the quasiperiodic pattern written into the template, and the term “a_phi” refers to a preferred Penrose tile edge used in presently preferred embodiments. In certain preferred embodiments, a_phi is defined by the relationships phi=(1+sqrt(5))/2, X_opt=phi/pi, and a_phi=(6pi)X_opta_B=6phi*a_B, where a_B is a fundamental atomic length scale. In preferred implementations, a_phi is used as a fabrication parameter that defines the written quasiperiodic template and, in certain embodiments, defines an effective lattice-related length scale associated with the resulting superconducting heterostructure, wherein that lattice-related length scale is derived from the stated RS relationships rather than empirically selected from alternatives or fitted to measured data.

As used throughout this disclosure, the term “ambient pressure” refers to ordinary non-extreme operating pressure conditions not requiring ultra-high compression environments such as diamond-anvil-cell conditions, and the term “room temperature” refers to an operating temperature regime at or above conventional ordinary-environment working temperature, such as approximately 300 K or greater, unless a different threshold is expressly specified. The term “critical temperature” or “T_c” refers to a temperature associated with transition into superconducting behavior, the term “critical current density” or “J_c” refers to current density that can be carried while maintaining superconducting performance under stated conditions, and the term “Meissner fraction” refers to a measured diamagnetic shielding or flux-expulsion-related quantity used to characterize superconducting response.

As used throughout this disclosure, the term “seed layer” refers to a layer provided on a substrate to facilitate subsequent pattern transfer, nucleation behavior, lattice accommodation, growth support, or other fabrication control functions. The term “patterned quasiperiodic template” refers to a physically realized quasiperiodic pattern formed at, in, or on a layer that participates in subsequent superconducting-film formation. The template may be topographic, structural, compositional, interfacial, energetic, or a combination thereof. In preferred embodiments the template includes physically recessed and raised features transferred into a seed layer. The term “superconducting film” refers to a deposited superconducting material layer that overlies, conforms to, is guided by, or is otherwise functionally influenced by the patterned quasiperiodic template.

As used throughout this disclosure, the term “five-fold quasiperiodic diffraction symmetry” refers to a diffraction response indicating quasiperiodic order compatible with Penrose-type five-fold symmetry rather than ordinary translational crystal periodicity. The term “computer-readable medium” refers to a non-transitory storage medium capable of storing digital pattern definitions, mask files, process recipes, growth settings, validation criteria, calibration data, or other machine-readable fabrication information. The term “mask file” includes GDS-II and equivalent layout representations. The term “flexible superconducting tape” refers to a tape-like conductor architecture formed on a flexible substrate or flexible supported structure. The term “Josephson junction” refers to a device including superconducting regions separated by a barrier region permitting Josephson behavior. The term “qubit lattice” refers to an ordered or quasiperiodically ordered arrangement of qubit-forming superconducting structures or associated coupling structures.

Referring now to FIG. 1, an overall fabrication architecture is shown in schematic form by fabrication system 100. Fabrication system 100 includes substrate 102, seed layer 104, patterned quasiperiodic template 106, superconducting film 108, oxygenation stage 110, characterization station 112, controller and recipe store 114, and finished superconducting article 116. FIG. 1 is not drawn to scale and is intended to show functional relationships rather than precise mechanical layout. Fabrication system 100 illustrates a manufacturing architecture in which a substrate-bearing stack is progressively transformed into a patterned superconducting article through controlled fabrication and validation operations.

Still referring to FIG. 1, substrate 102 may be any substrate capable of supporting subsequent patterned growth, including sapphire, buffered sapphire, oxide-compatible wafers, single-crystal oxide wafers, flexible metal-supported substrates, tape substrates, ceramic bodies, quasicrystal-compatible growth bodies, or other substrates suitable for the selected embodiment. In presently preferred embodiments, substrate 102 is a sapphire substrate, such as an r-plane sapphire substrate, selected for thermal stability, process compatibility, mechanical integrity, and compatibility with a subsequently formed or deposited seed layer. In other embodiments, substrate 102 may be selected based on coefficient-of-thermal-expansion considerations, lattice accommodation, process-tool compatibility, mechanical flexibility, cost, wafer-scale manufacturing requirements, or downstream device packaging requirements.

Still referring to FIG. 1, seed layer 104 is provided over substrate 102 and may function as a buffer layer, pattern-transfer layer, lattice-accommodation layer, nucleation-governing layer, or combined support layer. In preferred embodiments, seed layer 104 includes SrTiO3 deposited over substrate 102, although other oxide seed layers, buffer architectures, multilayer stacks, graded interfaces, diffusion-barrier layers, or nucleation-promoting layers may be used. Seed layer 104 may be selected to accept a transferred Penrose pattern with sufficient resolution, to preserve template fidelity during subsequent overgrowth, and to provide a stable interface for superconducting-film deposition. In some embodiments, seed layer 104 is physically distinct from substrate 102. In other embodiments, a functionally equivalent patterned region may be formed directly in substrate 102 or in an intermediate layer that collectively performs the seed-layer role.

Still referring to FIG. 1, patterned quasiperiodic template 106 is formed at or within the surface of seed layer 104 and is configured to impose a deterministic quasiperiodic growth condition rather than an uncontrolled disordered roughness condition. Patterned quasiperiodic template 106 may be implemented as a topographic relief pattern, a patterned surface-energy distribution, a patterned etch-depth architecture, a compositional modulation, a material-removal architecture, or a combined physical template in which geometry and interface characteristics jointly influence later film formation. In preferred embodiments, patterned quasiperiodic template 106 is formed by lithographically writing a Penrose pattern and transferring the pattern into the seed layer using a subtractive transfer process such as ion-beam milling. The resulting template may define preferred nucleation regions, altered local strain environments, local step-edge conditions, and deterministic quasiperiodic site relationships that guide later film growth.

Still referring to FIG. 1, superconducting film 108 is deposited over patterned quasiperiodic template 106 and may conform to the template topography, accommodate the template through local growth adaptation, or otherwise reflect the imposed quasiperiodic pattern in the resulting microstructure. In preferred embodiments, superconducting film 108 includes a cuprate superconductor such as YBa2Cu3O7-delta, but is not limited thereto. Superconducting film 108 may alternatively include BSCCO, Hg-based superconducting material, nickelate material, iron-based material, or other superconducting materials capable of being formed over a quasiperiodic template. In some embodiments superconducting film 108 is a single-layer film. In other embodiments superconducting film 108 may be part of a multilayer stack, junction device, tape conductor, or composite structure.

Still referring to FIG. 1, oxygenation stage 110 represents one or more post-deposition treatments used to tune oxygen content, stabilize stoichiometry, alter interfacial chemistry, reduce process variability, or otherwise support superconducting behavior. In preferred embodiments oxygenation stage 110 includes an ozone anneal performed under controlled temperature, duration, and pressure conditions. In other embodiments oxygenation stage 110 may include oxygen-rich annealing, multi-stage annealing, staged cooldown in oxygen-containing atmosphere, plasma-assisted oxygenation, or other oxygen-control treatments. Oxygenation stage 110 is shown separately in FIG. 1 because oxygenation is a distinct process stage contributing to the final superconducting article.

Still referring to FIG. 1, characterization station 112 represents one or more tools and workflows used to determine whether the fabricated article meets structural and superconducting objectives. Characterization station 112 may include diffraction analysis, transmission electron microscopy, atomic force microscopy, four-probe electrical testing, SQUID testing, current-density testing, metrology for template spacing, film-thickness measurement, roughness measurement, and reproducibility analysis across multiple samples.

Still referring to FIG. 1, controller and recipe store 114 may include a local controller, distributed controller, processor-based recipe manager, data store, non-transitory memory, fabrication execution engine, validation criteria engine, or combined digital process-control platform. Controller and recipe store 114 may store pattern files, mask definitions, deposition recipes, anneal parameters, acceptable process windows, metrology thresholds, lot-history information, corrective-action logic, and device-specific variations. In some embodiments controller and recipe store 114 provides machine-actionable outputs to lithography tools, deposition tools, anneal tools, and characterization tools. In other embodiments controller and recipe store 114 is used primarily for recipe archival, process reproducibility, and auditability. Finished superconducting article 116 may be a wafer-scale film, diced device precursor, tape segment, coil precursor, junction precursor, cable component, magnet component, or validated superconducting platform article for further fabrication.

Referring now to FIG. 2, a preferred Penrose-pattern geometry is shown schematically as Penrose pattern 200. Penrose pattern 200 includes kite tiles 202, dart tiles 204, tile edge a_phi 206, vertex set 208, inflation direction 210, quasiperiodic domain 212, and representative nesting vectors 214. FIG. 2 is a plan-view schematic and is not intended to depict every permissible Penrose arrangement or every exact geometric ratio at full fabrication scale. FIG. 2 illustrates the type of deterministic quasiperiodic geometry used to define the patterned template in presently preferred embodiments.

Still referring to FIG. 2, kite tiles 202 and dart tiles 204 represent one preferred Penrose tile basis. In other embodiments equivalent Penrose constructions may be defined by rhombus-based representations, dual tilings, vertex constructions, inflation-generated patterns, deflation-generated patterns, edge-substitution rules, or machine-generated equivalent deterministic quasiperiodic layouts. The pattern used for fabrication preferably preserves a deterministic quasiperiodic order capable of being written into a physical template and later reflected in the overgrown superconducting article. The invention therefore does not require a single visual representation of the Penrose pattern so long as the resulting template retains the desired quasiperiodic functional architecture.

Still referring to FIG. 2, tile edge a_phi 206 is the characteristic tile edge used to define the preferred written geometry. In presently preferred embodiments, tile edge a_phi 206 is selected in accordance with the relationships phi=(1+sqrt(5))/2, X_opt=phi/pi, and a_phi=(6pi)X_opta_B=6phi*a_B. Where a_B is taken as approximately 0.529 Angstrom, a preferred numerical estimate yields a_phi of approximately 5.15 Angstrom, or approximately 0.515 nm. The invention is not limited to a requirement that the preferred equation be the only possible spacing relation, but this preferred relation provides one presently preferred implementation.

Still referring to FIG. 2, vertex set 208 represents the deterministically distributed pattern vertices that define local site relationships within the quasiperiodic domain. In preferred embodiments, later-described nucleation behavior is influenced by these vertex-defined site relationships because adatoms may preferentially nucleate at, near, or relative to selected template features associated with the underlying Penrose geometry. Inflation direction 210 represents the self-similar character of the pattern and indicates that the quasiperiodic structure is not random but possesses a deterministic inflation-related organization. Quasiperiodic domain 212 represents the patterned region defined on the fabrication surface. Representative nesting vectors 214 indicate that multiple spatial scales and reciprocal-space relationships may be associated with the Penrose geometry rather than a single periodic lattice vector alone.

Still referring to FIG. 2, tile edge a_phi 206 is used directly in mask generation, pattern writing, or template definition and therefore becomes part of the actual manufacturing architecture. As a result, the fabricated article can be described not only by what material is present, but also by how that material is physically guided by a concrete quasiperiodic template having a disclosed scale.

Still referring to FIG. 2, the presently preferred Penrose pattern may be generated computationally before lithographic transfer. In some embodiments pattern generation is performed by inflation rules, substitution rules, deterministic vertex propagation, edge-matching algorithms, direct CAD construction, or a stored mask-file workflow. In some embodiments the pattern is clipped to a finite write domain while preserving quasiperiodic determinism within the active device region. In other embodiments edge-handling logic may be used to avoid incomplete tile artifacts near pattern boundaries, to preserve write continuity across fields, or to optimize manufacturability for a selected lithography platform. Such pattern-generation choices do not depart from the invention so long as the resulting physically transferred template retains the intended quasiperiodic character.

Referring now to FIG. 3, a patterned stack after template formation is shown schematically as layered assembly 300. Layered assembly 300 includes sapphire substrate 302, seed layer 304, recessed template features 306, raised template features 308, template profile 310, preferred nucleation sites 312, superconducting film 314, and oxygenated surface region 316. FIG. 3 is a schematic cross-sectional representation showing how the quasiperiodic template may be embodied physically in the growth stack before and after superconducting-film formation.

Still referring to FIG. 3, sapphire substrate 302 is a presently preferred implementation of substrate 102 from FIG. 1, although other substrate materials may be substituted. Seed layer 304 is shown disposed over sapphire substrate 302 and may include SrTiO3 in presently preferred embodiments. Seed layer 304 may be deposited by sputtering, pulsed-laser deposition, molecular beam epitaxy, chemical vapor deposition, atomic layer deposition, or another suitable process depending on the desired thickness, crystalline quality, interface structure, and pattern-transfer compatibility. In certain preferred embodiments, seed layer 304 has a thickness sufficient to receive a shallow quasiperiodic transfer while preserving continuity and providing a stable overgrowth surface.

Still referring to FIG. 3, recessed template features 306 and raised template features 308 collectively define a surface-relief expression of the patterned quasiperiodic template. Recessed template features 306 may be formed by localized material removal during a transfer process such as ion-beam milling, while raised template features 308 may be the remaining portions of seed layer 304 after transfer. In some embodiments the depth contrast between recessed template features 306 and raised template features 308 is selected to influence local adatom attachment kinetics without causing destructive discontinuity in later film growth. In other embodiments the template amplitude may be tuned to balance pattern fidelity, growth continuity, and manufacturability. Template profile 310 represents the local topographic contour that results from the transferred Penrose geometry.

Still referring to FIG. 3, preferred nucleation sites 312 represent local locations at which later-deposited superconducting material may preferentially attach, accumulate, organize, or stabilize during growth. Preferred nucleation sites 312 may correspond to template vertices, edge intersections, local minima, local maxima, slope transitions, or other template-defined features that change the local energy landscape of growth. The term “preferred” in this context does not require perfect exclusive nucleation at those sites. Rather, it indicates that the template creates a deterministic bias toward selected growth behavior relative to an unpatterned control surface. In preferred embodiments this deterministic bias contributes to formation of a film whose resulting architecture reflects the underlying quasiperiodic template rather than a merely random disorder state.

Still referring to FIG. 3, superconducting film 314 is deposited over the templated seed layer and may progressively overgrow both recessed template features 306 and raised template features 308. In some embodiments superconducting film 314 partially conforms to the topography while smoothing certain small-scale relief features as thickness increases. In other embodiments the template influences initial nucleation and local ordering more strongly than final surface shape, such that the film records the templating effect structurally or crystallographically even if the outer surface becomes smoother than the original relief. Oxygenated surface region 316 represents one or more portions of the completed or partially completed stack influenced by post-deposition oxygenation treatment, such as an ozone anneal.

Still referring to FIG. 3, layered assembly 300 provides a substrate-seed-template-film stack that can serve as a precursor for conductor, junction, magnet, levitation, and related embodiments described herein. The physical relationship among sapphire substrate 302, seed layer 304, recessed template features 306, raised template features 308, superconducting film 314, and oxygenated surface region 316 illustrates one preferred form of a patterned superconducting article.

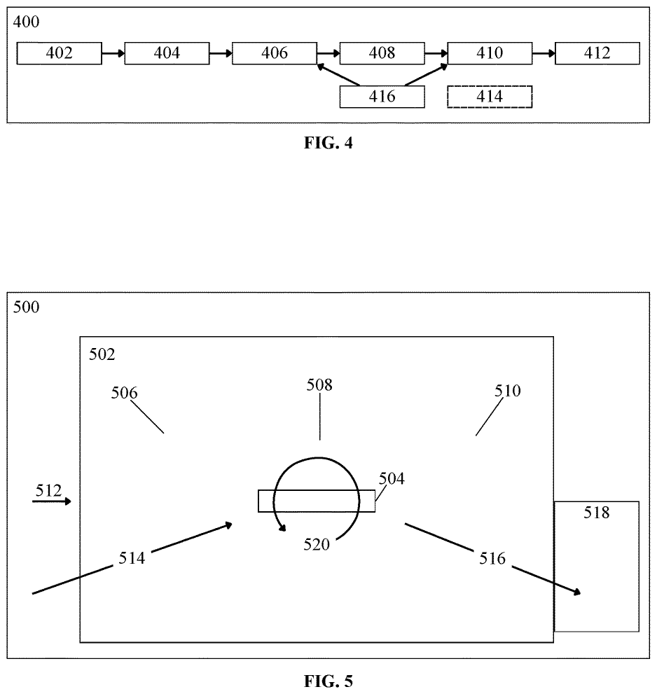

Referring now to FIG. 4, a preferred quasiperiodic patterning workflow is shown schematically as lithography process 400. Lithography process 400 includes substrate and seed precursor 402, resist coat 404, e-beam patterning step 406, developed resist openings 408, ion-beam transfer step 410, patterned quasiperiodic template 412, write field 414, and patterning controller and stage 416. FIG. 4 illustrates one presently preferred route for generating the patterned quasiperiodic template physically on the seed layer.

Still referring to FIG. 4, substrate and seed precursor 402 may correspond to a stack including a substrate, such as sapphire, and a previously deposited seed layer, such as SrTiO3. Resist coat 404 is applied over the exposed surface of the seed layer and may be a positive resist, negative resist, electron-beam resist, chemically amplified resist, nanoimprint resist, or other patternable material compatible with the selected patterning process. In preferred embodiments resist coat 404 is a positive electron-beam resist, such as ZEP-based resist, applied at a thickness sufficient to preserve high-resolution feature definition while also allowing later transfer into the seed layer.

Still referring to FIG. 4, e-beam patterning step 406 represents writing of the Penrose geometry into the resist layer using an electron-beam lithography system. In preferred embodiments, a high-voltage e-beam tool is used, such as a nominal 100 kV tool, although the invention is not limited thereto. Patterning controller and stage 416 may provide beam steering, stage positioning, field stitching logic, pattern scaling, dose control, and correction for drift or write distortions. Because a quasiperiodic pattern does not repeat periodically in the manner of a simple grid, pattern generation and write control may require deterministic layout management to preserve the intended Penrose relationships across the active write area. In preferred embodiments write field 414 is selected to reduce or avoid stitching artifacts that could otherwise disrupt quasiperiodic continuity.

Still referring to FIG. 4, developed resist openings 408 are formed after development of the exposed resist. In preferred embodiments the development chemistry and timing are chosen so that the Penrose-defined openings reproduce the intended tile edge and vertex relationships with sufficient fidelity for later transfer into the seed layer. Development conditions may be selected based on resist chemistry, feature scale, target depth, substrate temperature, and pattern-density effects. In some embodiments development bias correction may be included in the original mask file or exposure schedule so that the final developed geometry more closely matches the intended Penrose layout after processing.

Still referring to FIG. 4, ion-beam transfer step 410 transfers the developed quasiperiodic resist pattern into the underlying seed layer to create patterned quasiperiodic template 412. In preferred embodiments the transfer process is an Ar ion-beam milling operation producing shallow relief features in the seed layer. The transferred depth may be selected to create a functionally significant topographic template while preserving seed-layer continuity and avoiding excessive damage. In some embodiments the transfer depth is on the order of a few nanometers. In other embodiments the depth may be adjusted depending on material hardness, film-thickness target, desired nucleation contrast, and process-tool characteristics.

Still referring to FIG. 4, patterned quasiperiodic template 412 is the product of the patterning workflow and corresponds generally to patterned quasiperiodic template 106 of FIG. 1 and the relief features shown in FIG. 3. Write field 414 indicates that finite lithographic fields may be used to define the pattern over a selected area, such as an active device region, a test coupon, a wafer section, or a full-wafer process window. In preferred embodiments the patterning workflow is chosen to preserve deterministic quasiperiodic continuity across the useful device area. Where field boundaries are present, they may be placed outside critical active regions, corrected by overlap logic, or otherwise managed to avoid a field-boundary artifact being mistaken for intended quasiperiodic structure.

Still referring to FIG. 4, lithography process 400 is not limited to electron-beam writing as the only pattern-definition route. In alternative embodiments, a nanoimprint workflow may be used in which a Penrose-pattern master is formed once and then repeatedly impressed or otherwise replicated into a processable resist or template-forming layer. Such a nanoimprint route may be advantageous for high-throughput wafer-scale or panel-scale manufacturing because it can reduce direct-write time while preserving deterministic quasiperiodic geometry. In such embodiments the imprint template itself may be fabricated from a master Penrose mask, and the resulting imprint pattern may then be transferred into the seed layer by etch or milling techniques analogous to those described above.

Still referring to FIG. 4, other alternative pattern-definition routes may include direct etch writing, interference-assisted pattern guidance, hybrid mask-and-write methods, step-and-repeat quasiperiodic block construction, focused-ion-beam patterning, or patterned material deposition followed by planarization and selective exposure. The invention is not limited to one exact patterning technology so long as the final physical result is a deterministic quasiperiodic template suitable for guiding subsequent superconducting-film formation.

Referring now to FIG. 5, a preferred oxide deposition arrangement is shown as MBE system 500. MBE system 500 includes process chamber 502, substrate holder 504, yttrium source 506, barium source 508, copper source 510, oxygen and ozone inlet 512, RHEED emitter 514, RHEED detector 516, vacuum assembly 518, and stage-rotation drive 520. FIG. 5 shows one presently preferred system for depositing a cuprate superconducting film over the patterned quasiperiodic template.

Still referring to FIG. 5, process chamber 502 may be an oxide molecular beam epitaxy chamber configured for controlled co-deposition of superconducting film constituents under vacuum conditions compatible with high-purity thin-film growth. Vacuum assembly 518 may include pumps, gauges, valves, gas handling components, and pressure-control hardware sufficient to maintain the desired chamber environment before, during, and after deposition. In preferred embodiments, vacuum assembly 518 supports base pressure conditions below approximately 1×10\hat{ }−9 mbar prior to growth. Substrate holder 504 supports the patterned precursor stack during deposition and may include heating capability, thermal uniformity control, mounting features, backside thermal contact structures, and alignment features.

Still referring to FIG. 5, yttrium source 506, barium source 508, and copper source 510 represent source materials used to co-deposit a YBa2Cu3O7-delta film in a presently preferred embodiment. In preferred implementations the sources are individually controllable and are adjusted to achieve an approximate Y:Ba:Cu flux ratio of 1:2:3, with acceptable process tolerances selected according to the specific tool and process objectives. Oxygen and ozone inlet 512 provides one or more oxidizing species during growth, and may include molecular oxygen, ozone, mixed oxygen species, plasma-activated oxygen, or staged oxidant delivery depending on the embodiment.

Still referring to FIG. 5, stage-rotation drive 520 may rotate substrate holder 504 during deposition in order to improve flux uniformity, reduce azimuthal deposition asymmetry, support thickness uniformity, and promote consistent overgrowth conditions across the patterned surface. In preferred embodiments stage rotation is approximately 12 rpm, although this value is exemplary and may be adjusted. Substrate holder 504 is preferably maintained at a growth temperature suitable for forming the selected superconducting film. In preferred embodiments for YBa2Cu3O7-delta deposition, the growth temperature is approximately 720 C. A slower growth rate, such as approximately 0.1 nm/min, may be used to favor controlled ordering and template-responsive growth behavior.

Still referring to FIG. 5, RHEED emitter 514 and RHEED detector 516 provide an in situ monitoring arrangement by which surface evolution may be observed during growth. In preferred embodiments the RHEED arrangement is used to assess surface quality, growth mode, and development of ordering behavior. In some embodiments RHEED data may be logged and associated with controller and recipe store 114 for process traceability and lot comparison.

Still referring to FIG. 5, the patterned quasiperiodic template beneath the deposition front is believed, in preferred embodiments, to influence local growth kinetics such that adatoms preferentially nucleate or stabilize at template-related sites. This can produce a self-limiting or self-biasing step-edge behavior in which the underlying Penrose-derived architecture contributes to the developing film order. The templated surface thereby creates a deterministic growth bias capable of yielding a superconducting film that is structurally distinguishable from one grown on an unpatterned or merely roughened control substrate.

Referring now to FIG. 6, a preferred post-deposition oxygenation arrangement is shown schematically as anneal system 600. Anneal system 600 includes anneal chamber 602, film stack 604, ozone inlet 606, heater 608, pressure controller 610, cooling path 612, and exhaust 614. FIG. 6 illustrates one presently preferred approach for adjusting oxygen content and stabilizing the deposited superconducting film after overgrowth on the patterned quasiperiodic template. The figure is schematic and is not intended to limit the invention to a single chamber geometry, gas-flow path, or heating arrangement.

Still referring to FIG. 6, film stack 604 may correspond to a structure including a substrate, a seed layer, a patterned quasiperiodic template, and a deposited superconducting film, such as the structures described with respect to FIGS. 1, 3, and 5. Anneal chamber 602 may be any chamber capable of receiving film stack 604 and exposing it to a controlled oxygen-containing atmosphere under selected thermal and pressure conditions. In presently preferred embodiments, anneal chamber 602 is configured to receive an ozone-containing gas flow from ozone inlet 606 while heater 608 raises or maintains the stack at a selected anneal temperature and pressure controller 610 maintains the chamber within a target pressure range.

Still referring to FIG. 6, ozone inlet 606 may introduce ozone alone or may introduce ozone together with oxygen or another carrier gas. In preferred embodiments the post-deposition treatment includes an ozone anneal at approximately 300 C for approximately 3 minutes at approximately 200 mbar ozone pressure. In some embodiments the anneal temperature may be adjusted upward or downward based on the selected superconducting material, film thickness, oxygen sensitivity, substrate compatibility, or desired stoichiometric result. In some embodiments the duration may be lengthened to drive greater oxygen penetration or shortened to reduce over-processing risk. In some embodiments the pressure may be changed to tune oxidation kinetics or to accommodate chamber capability.

Still referring to FIG. 6, heater 608 may be resistive, radiative, conductive, inductive, or otherwise configured to raise the temperature of film stack 604 in a controlled manner. Pressure controller 610 may include pressure sensors, valves, gas-flow regulators, and closed-loop control logic. Cooling path 612 represents a controlled cooldown regime following anneal. In preferred embodiments cooling path 612 includes cooling in an ozone-containing atmosphere, or at least in an oxygen-containing atmosphere, so that the film does not suffer uncontrolled oxygen loss during temperature reduction. Exhaust 614 removes used gas and may be part of a gas-handling system configured for ozone-compatible operation.

Still referring to FIG. 6, the anneal step is significant because the superconducting film, particularly in cuprate embodiments, may depend strongly on oxygen stoichiometry and local oxygen distribution. The disclosed post-deposition oxygenation is therefore not merely a generic heat treatment. Rather, it is a controlled process stage used to place the deposited film into a desired compositional and superconducting state. In preferred YBa2Cu3O7-delta embodiments, the anneal may target a delta value around approximately 0.05, although the invention is not limited to that exact value. In other material systems, the post-deposition treatment may target a different oxygen state, a vacancy distribution, a reduced-oxygen configuration, a multi-step oxidation history, or another chemistry appropriate to the selected superconducting material.

Still referring to FIG. 6, the oxygenation treatment may also influence interfacial quality, strain relaxation behavior, near-surface chemistry, and defect-state distribution. In some embodiments the anneal contributes to sharpening of the superconducting transition, increasing Meissner response, improving current-density performance, or reducing sample-to-sample variation. In other embodiments the anneal may be used as a tuning step during process development, where multiple candidate oxygenation profiles are compared against structural and electrical results.

Still referring to FIG. 6, alternative post-deposition treatments may be employed without departing from the invention. By way of non-limiting example, the film may be exposed to a multi-stage oxygenation schedule including an initial higher-temperature oxygenation phase followed by a lower-temperature stabilization phase. In another embodiment the film may be oxygenated in a plasma-assisted environment. In another embodiment the film may be annealed in oxygen without ozone. In another embodiment an oxidant partial pressure may be dynamically ramped during cooldown. In another embodiment multiple anneal cycles may be used. In each case the function of the post-deposition treatment is to place the superconducting film into a desired state while preserving the templated quasiperiodic architecture produced by the earlier fabrication stages.

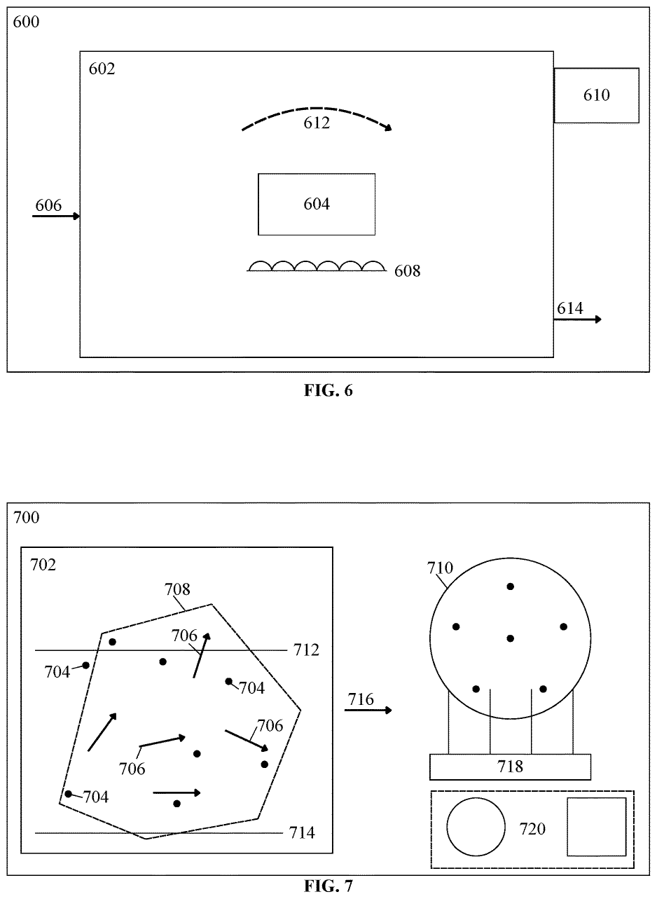

Referring now to FIG. 7, a resulting quasiperiodic superconducting microstructure is shown schematically as microstructure 700. Microstructure 700 includes superconducting film 702, Penrose-vertex nucleation sites 704, local grain-orientation vectors 706, quasiperiodic order domain 708, five-fold diffraction feature 710, CuO2 plane region 712, strain field region 714, growth front 716, four-probe sample arrangement 718, and SQUID and metrology arrangement 720. FIG. 7 combines structural and representative characterization concepts to illustrate how a fabricated film may be understood in relation to its templated growth origin.

Still referring to FIG. 7, superconducting film 702 represents the overgrown superconducting layer after deposition and oxygenation. In presently preferred embodiments superconducting film 702 is a cuprate film, such as YBa2Cu3O7-delta, having a nominal thickness on the order of approximately 80 nm, although other thicknesses may be used. Penrose-vertex nucleation sites 704 represent local locations where the templated geometry is believed to influence initial or continuing nucleation behavior. The underlying template thereby introduces a deterministic quasiperiodic bias into the film-formation process.

Still referring to FIG. 7, local grain-orientation vectors 706 indicate that local grain or domain orientation may vary across the film while still participating in a broader quasiperiodic order domain 708. Quasiperiodic order domain 708 represents a region over which the fabricated film exhibits structural order compatible with the underlying template. In some embodiments the domain size may extend over micrometer-scale or greater regions. In some embodiments the structural quality may vary from region to region within a wafer or sample. In some embodiments process optimization may be directed specifically toward increasing the spatial extent, consistency, or quality of quasiperiodic order domain 708.

Still referring to FIG. 7, five-fold diffraction feature 710 represents a structural signature supporting the conclusion that the fabricated article exhibits five-fold quasiperiodic order rather than merely random disorder or ordinary periodic crystal behavior. In some embodiments five-fold diffraction feature 710 is observed by transmission electron microscopy, selected-area diffraction, electron diffraction, or another structural characterization technique. The presence of such a feature provides objective evidence that the templated growth architecture produced a physical article consistent with the disclosed quasiperiodic design strategy.

Still referring to FIG. 7, CuO2 plane region 712 represents a region within the superconducting film associated with superconducting transport in preferred cuprate embodiments. Strain field region 714 represents a locally modified structural environment that may arise from the imposed quasiperiodic template. In preferred embodiments the patterned tile edge and corresponding topographic or interfacial architecture alter the local strain state in a way that contributes to the resulting superconducting behavior. Growth front 716 represents the advancing film-formation interface during deposition and emphasizes that the resulting article is the product of a guided growth process rather than a post hoc assignment of quasiperiodicity.

Still referring to FIG. 7, four-probe sample arrangement 718 and SQUID and metrology arrangement 720 indicate that the structural article shown is suitable for subsequent performance validation. Four-probe sample arrangement 718 signifies that the film may be contacted and electrically measured. SQUID and metrology arrangement 720 signifies that magnetic and dimensional characterization may also be applied to the same or related samples. FIG. 7 therefore links the resulting microstructure to subsequent validation measurements.

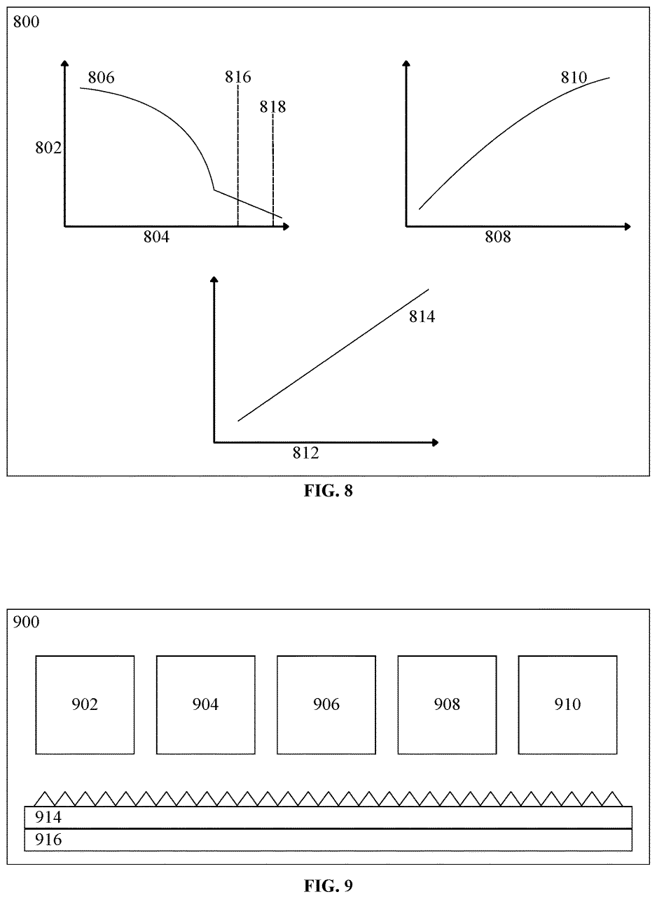

Referring now to FIG. 8, a characterization and performance plot set is shown schematically as chart set 800. Chart set 800 includes resistance axis 802, temperature axis 804, resistive transition curve 806, Meissner axis 808, Meissner curve 810, critical-current axis 812, critical-current curve 814, predicted T_c marker 816, and measured T_c marker 818. FIG. 8 is a schematic figure and is not intended to limit the shape, scale, or exact numerical values of the plotted curves to only those shown. FIG. 8 illustrates that the fabricated article can be characterized by measurable electrical and magnetic outputs.

Still referring to FIG. 8, resistance axis 802 and temperature axis 804 define a representative resistive transition plot on which resistive transition curve 806 may be shown. In preferred embodiments resistive transition curve 806 indicates a transition to zero-resistance or substantially zero-resistance behavior at a temperature associated with the superconducting transition of the fabricated article. In certain presently preferred embodiments the onset or measured transition value is approximately 428 K, with some variation across samples or measurement conditions. Measured values may depend on material system, sample geometry, process history, test protocol, and acceptance criteria.

Still referring to FIG. 8, Meissner axis 808 and Meissner curve 810 represent a magnetic-response measurement by which diamagnetic shielding or related Meissner behavior is evaluated. In preferred embodiments Meissner curve 810 indicates a Meissner fraction greater than approximately 95 percent at 350 K. Such a value is exemplary for certain embodiments and is not required in every implementation. This measurement distinguishes a superconducting state from a low-resistance condition lacking robust diamagnetic response.

Still referring to FIG. 8, critical-current axis 812 and critical-current curve 814 represent a current-density or current-related performance measurement. In presently preferred embodiments, critical-current curve 814 corresponds to a J_c value on the order of approximately 3×10\hat{ }6 A/cm\hat{ }2 at 300 K. In other embodiments J_c may vary with geometry, film quality, operating field, material system, thickness, and measurement method. The fabricated article may therefore be evaluated not only by transition temperature but also by current-carrying performance relevant to conductor and magnet embodiments.

Still referring to FIG. 8, predicted T_c marker 816 and measured T_c marker 818 indicate that the disclosure contemplates both measured performance data and a separate explanatory framework that may predict or estimate T_c. In some embodiments the predicted and measured values may be close, such as a predicted value of approximately 430 K and a measured value of approximately 428 K. In other embodiments process variation or alternative material systems may produce a different relationship between predicted and measured performance. The fabricated article and method remain within the invention even where theory and measured data are not identical, provided the article is formed according to the disclosed fabrication architecture.

Referring now to a non-limiting explanatory framework associated with the disclosed invention, the following discussion describes one presently preferred technical explanation for the observed or predicted superconducting behavior of the disclosed patterned structures. The physical fabrication architecture, the patterned template, the superconducting article, the validation workflow, and the resulting device embodiments remain part of the invention regardless of whether a particular explanatory model is ultimately adopted, modified, or replaced.

With respect to the quasiperiodic density-of-states explanation, the disclosed Penrose-derived architecture is believed in preferred embodiments to create a reciprocal-space environment richer or more densely structured than that of a simple periodic lattice. A quasiperiodic arrangement may generate sharper or more numerous effective density-of-states features because the underlying structural order is deterministic yet non-periodic. The location and shape of available electronic-state features may influence superconducting pairing behavior, energy distribution, and transport-relevant conditions. In preferred embodiments the imposed quasiperiodic tile edge and corresponding growth architecture are selected so that the fabricated article tends toward a density-of-states environment favorable to elevated-temperature superconducting behavior.

With respect to the phonon-related explanation, the disclosed quasiperiodic template is believed in certain embodiments to alter local lattice dynamics, including phonon softening or redistribution of relevant modes, relative to a periodic control lattice. Because the structure lacks ordinary translational periodicity while preserving deterministic order, certain scattering pathways and local vibrational environments may differ from those in a conventional crystal. In preferred embodiments such differences contribute to a stronger effective pairing environment or more favorable superconducting response.

With respect to the multi-scale nesting explanation, the Penrose geometry is believed to introduce multiple relevant spatial scales associated with phi-related self-similarity. Instead of relying on one periodic reciprocal-space vector alone, the quasiperiodic structure may support multiple nesting vectors or scale-related interactions. In the preferred explanatory framework, these multiple scales contribute to enhanced pairing pathways or broadened opportunities for cooperative superconducting behavior.

With respect to the disclosed J-cost framework, one preferred explanatory form uses the relationship J(X)=0.5*(X+1/X)−1. In that framework, paired reciprocal recognition states satisfy J(x*(1/x))=J(1)=0, and J(x*(1/x))<J(x)+J(1/x), for x>0 and x!=1. This formulation is presented as one non-limiting way of describing why paired states may be favored over corresponding unpaired states. Whether viewed as a theoretical derivation, a heuristic model, or a presently preferred explanatory formalism, the fabricated article does not depend for its existence on acceptance of that explanation. In certain preferred embodiments, the recognition-science relationships associated with the disclosed design choice are also formalized and machine-verified in Lean 4, including formalizations corresponding to cooper_pair_zero_cost, cooper_pairing_lowers_cost, and jcost_symmetric, thereby providing a formally verified basis for the preferred RS-derived lattice-defining scale.

With respect to superconducting-gap and critical-temperature relations, the preferred explanatory framework may use the expressions Delta(0)=2hbaromega_Dexp(−1/(N_0V)), 2Delta/(k_BT_c) approx 3.52, and T_c=(hbaromega_D/k_B)exp(−1/(N_0V)). In this context, the quasiperiodic architecture is believed to alter one or both of omega_D and N_0V relative to a periodic control material. By way of example, the framework may assume omega_D_prime approx phiomega_D_0 and (N_0V)_prime approx (phi\hat{ }2)(N_0*V)_0, thereby yielding an elevated predicted T_c compared with the periodic reference material.

With respect to the Penrose-bridge explanation, the preferred framework may further use the relations Q_n=Q_0*(phi\hat{ }n), V_total=sum_n V(Q_n) approx V_0sum_n(phi\hat{ }(−n))=V_0phi/(phi−1)=V_0*(phi\hat{ }2), and J(phi)=phi−3/2. In this explanatory form, phi-related self-similarity and quasiperiodic ordering are treated as contributing to a preferred aperiodic coherence structure. These expressions are non-limiting and do not confine the invention to any particular mathematical proof or theoretical interpretation.

With respect to a preferred numerical example, the explanatory framework may start from a control material state in which omega_D_0 approx 50 meV and (N_0V)_0 approx 0.25. Under the preferred phi-scaled assumptions noted above, omega_D_prime approx 81 meV and (N_0V)_prime approx 0.655, leading to T_c_prime approx 429 K. This preferred numerical example is close to the presently preferred measured transition value described elsewhere in this disclosure. The invention is not limited to that exact numerical route, and other material systems, process settings, or interpretive models may be used. In certain preferred embodiments, formal verification of the recognition-science framework is provided in a Lean 4 file designated RecognitionPenroseSuperconductor.lean. In preferred implementations, the formalization includes theorems corresponding to lattice_constant_from_phi, lattice_constant_positive, cooper_pair_zero_cost, cooper_pairing_lowers_cost, jcost_symmetric, penrose_cost, and penrose_inflation_phi. This formal-verification material provides additional support for the preferred RS-derived lattice-defining scale while not limiting the invention to any single explanatory model.

Referring now to FIG. 9, alternative superconducting material embodiments are shown schematically as material set 900. Material set 900 includes YBCO layer 902, BSCCO layer 904, Hg-based layer 906, nickelate layer 908, iron-based layer 910, common Penrose template 912, common seed layer 914, and alternative substrate 916. FIG. 9 emphasizes that the invention is not limited to a single superconducting chemistry even though YBa2Cu3O7-delta is presently preferred for certain embodiments.

Still referring to FIG. 9, YBCO layer 902 represents a presently preferred superconducting film embodiment because YBa2Cu3O7-delta is a known cuprate system capable of thin-film fabrication and because presently preferred embodiments are centered on a Penrose-patterned YBCO implementation. In preferred embodiments YBCO layer 902 is deposited over common Penrose template 912 and common seed layer 914 under the process conditions described with respect to FIG. 5 and is subsequently oxygenated as described with respect to FIG. 6.

Still referring to FIG. 9, BSCCO layer 904 represents an alternative embodiment in which Bi2Sr2Ca2Cu3O10, such as a BSCCO-2223 family material, is used as the superconducting film. In such embodiments the templated Penrose architecture may still be used to provide deterministic quasiperiodic growth guidance. Process conditions may be modified to account for the chemistry, volatility, layering behavior, or thermal requirements of BSCCO-based deposition. In some embodiments BSCCO layer 904 may be selected because its anisotropy or layered nature provides a distinct interaction with the quasiperiodic template compared with YBCO.

Still referring to FIG. 9, Hg-based layer 906 represents another alternative embodiment in which an Hg-containing superconducting material is formed over the templated architecture. Because mercury-containing materials may involve special safety and process considerations, an Hg-based implementation may use modified source containment, deposition control, toxic-material handling procedures, and post-process environmental controls. Nonetheless, the underlying architecture remains the same in that a deterministic quasiperiodic template is formed first and the superconducting material is deposited over that template.

Still referring to FIG. 9, nickelate layer 908 represents a non-cuprate embodiment in which a nickelate superconductor, such as an NdNiO2-related system or another nickelate material, is formed over the Penrose-derived template. In a nickelate embodiment, the deposition chemistry, atmosphere control, reduction state, and post-processing sequence may differ from a cuprate implementation. Even so, the same core concept remains applicable, namely that a patterned quasiperiodic template may be used to influence growth and resulting superconducting behavior in a deterministic and reproducible way.

Still referring to FIG. 9, iron-based layer 910 represents another non-cuprate embodiment, such as an FeSe-based or related iron-based superconducting material. As with the nickelate embodiment, the preferred process conditions may differ from the cuprate example. The Penrose-patterned architecture may nevertheless be used with iron-based systems by following the general sequence of substrate preparation, seed-layer or support-layer preparation, quasiperiodic pattern definition, superconducting deposition, post-deposition treatment as needed, and validation.

Still referring to FIG. 9, common Penrose template 912 and common seed layer 914 indicate that different superconducting chemistries may share a common templated foundation. In some embodiments the same template geometry may be reused while source materials, thermal profiles, oxygenation conditions, or validation thresholds are changed. In some embodiments alternative substrate 916 may be employed to suit a selected material system, including substrates chosen for thermal match, lattice accommodation, flexibility, tape compatibility, or process-specific reasons.

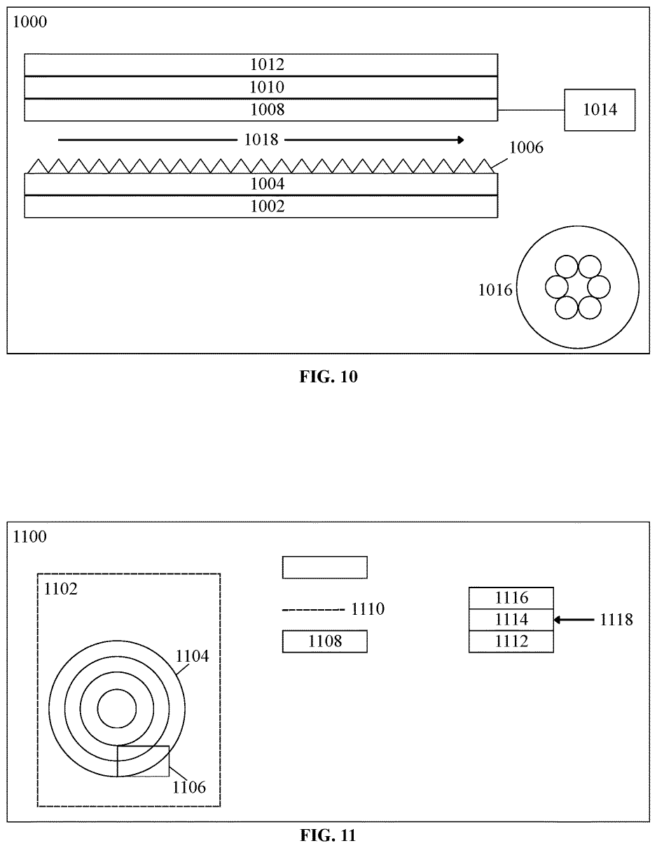

Referring now to FIG. 10, a flexible-tape and cable embodiment is shown schematically as flexible superconducting tape 1000. Flexible superconducting tape 1000 includes metallic substrate 1002, buffer layer 1004, patterned template 1006, superconducting layer 1008, stabilizer layer 1010, insulating jacket 1012, conductor terminal 1014, cable assembly 1016, and current path 1018. FIG. 10 illustrates how the patterned superconducting article may be embodied in a flexible conductor suitable for cable, interconnect, or other current-carrying applications.

Still referring to FIG. 10, metallic substrate 1002 may be a flexible metal tape, such as a Hastelloy tape, stainless-steel tape, or another mechanically robust conductive or support substrate capable of participating in roll-to-roll or semi-continuous processing. Buffer layer 1004 may be an oxide buffer, seed layer, diffusion barrier, texturing layer, or combined support structure selected to permit formation of patterned template 1006 and later deposition of superconducting layer 1008. Patterned template 1006 may be formed by a direct-write, nanoimprint, or replicated Penrose-pattern process adapted as needed for a tape geometry.

Still referring to FIG. 10, superconducting layer 1008 may be formed over patterned template 1006 using a cuprate or other superconducting chemistry as described earlier. In some embodiments superconducting layer 1008 is then combined with stabilizer layer 1010, which may provide mechanical protection, electrical stabilization, thermal spreading, or combined functions. Insulating jacket 1012 may be added where the resulting article is to be used in cable assembly 1016. Conductor terminal 1014 represents one or more terminations, contacts, or connector structures by which the flexible superconducting tape is electrically integrated into a larger device or system. Current path 1018 indicates the intended current-carrying direction through the resulting tape or cable embodiment.

Still referring to FIG. 10, the flexible-tape embodiment supports several distinct application modes. In one mode, cable assembly 1016 is used for power transmission, including room-temperature or elevated-temperature low-loss power transmission. In another mode, the same tape architecture may be used for power-grid interconnect structures. In another mode, shortened or finer-pitch forms of the conductor may be used as high-performance interconnect structures in computing or data-center environments. In each case, the patterned superconducting article is fabricated on a flexible support and then packaged, terminated, and integrated into a conductor system.

Still referring to FIG. 10, the tape architecture may be fabricated in batch, semi-continuous, or roll-to-roll form. In some embodiments a tape precursor is first provided, after which buffer layer 1004 is formed, patterned template 1006 is defined over selected tape regions, superconducting layer 1008 is deposited, oxygenation is performed, and stabilizer or insulation layers are added. In some embodiments pattern formation may be performed by nanoimprint to support higher throughput. In some embodiments validation may be performed segment by segment. In some embodiments non-conforming segments may be rejected, reworked, or assigned to lower-performance applications.

Referring now to FIG. 11, a magnet, levitation, and junction-device embodiment is shown schematically as magnet system 1100. Magnet system 1100 includes superconducting conductor 1102, coil winding 1104, support former 1106, Penrose superconducting tile 1108, levitation gap 1110, first superconducting layer 1112, barrier layer 1114, second superconducting layer 1116, and magnetic-flux input region 1118. FIG. 11 combines closely related device-level embodiments that derive from the same patterned superconducting platform article. The figure therefore illustrates non-limiting device integrations rather than requiring that every component shown be present in a single finished product.

Still referring to FIG. 11, superconducting conductor 1102 may be a conductor segment derived from a patterned superconducting film fabricated according to the processes described above. In one embodiment superconducting conductor 1102 is wound into coil winding 1104 around support former 1106 to produce a magnet structure. Support former 1106 may be a cylindrical former, racetrack former, segmented former, laminated support body, or another mechanical support architecture configured to hold the superconducting conductor in a controlled winding geometry. In some embodiments the resulting magnet system 1100 is used in an MRI device. In some embodiments the resulting magnet system 1100 is used in an NMR system. In some embodiments the resulting magnet system 1100 is used in a particle-accelerator magnet, such as a dipole or quadrupole magnet. In some embodiments the resulting magnet system 1100 is used in a superconducting magnetic energy storage system.

Still referring to FIG. 11, coil winding 1104 may be formed from one or more lengths of superconducting conductor 1102, including tape-based conductors like those described with respect to FIG. 10. The winding geometry may be solenoidal, toroidal, racetrack, saddle-shaped, segmented, layered, or otherwise selected for the intended field profile and packaging requirements. In preferred embodiments the patterned superconducting article provides a conductor capable of practical current carriage at elevated temperature or room temperature, thereby reducing or eliminating the need for conventional cryogenic support. In other embodiments cooling margins, environmental controls, or thermal stabilization may still be employed depending on the intended application.

Still referring to FIG. 11, the magnet embodiment is not limited to a specific field strength, bore size, stored energy, or coil count. In an MRI implementation, support former 1106 and coil winding 1104 may be configured around an imaging bore or patient volume. In an NMR implementation, the winding may be configured for a stable field region associated with analytical measurement. In a particle-accelerator implementation, the winding may be configured to generate steering, focusing, or transport fields. In an SMES implementation, the winding may be configured to store current in a persistent or semi-persistent loop for later discharge.

Still referring to FIG. 11, Penrose superconducting tile 1108 and levitation gap 1110 illustrate a magnetic-levitation embodiment. In that embodiment, Penrose superconducting tile 1108 may be a tile, strip, panel, or modular substrate structure carrying a patterned superconducting article fabricated according to the processes disclosed herein. Levitation gap 1110 represents the spacing between the superconducting element and an opposing magnetic element, such as a vehicle-borne magnet, track-borne magnet, or another field source. In use, the superconducting tile can participate in a flux-pinning or levitation regime that supports contactless transport or stabilizing force generation. The invention is not limited to a single exact levitation gap, and quoted values elsewhere in the disclosure are exemplary.

Still referring to FIG. 11, the levitation embodiment may be implemented as a guideway, support track, transport pad, magnetic bearing surface, or other levitation-supporting structure. In some embodiments Penrose superconducting tile 1108 is repeated in an array. In some embodiments the tile is formed on a rigid support rather than a flexible tape. In some embodiments the superconducting layer is protected by encapsulation, environmental shielding, or structural overmolding. The same patterned superconducting platform article can thereby be integrated into a levitation-supporting device architecture without altering the underlying fabrication concept.

Still referring to FIG. 11, first superconducting layer 1112, barrier layer 1114, second superconducting layer 1116, and magnetic-flux input region 1118 illustrate a Josephson-junction and SQUID-related embodiment. In one implementation first superconducting layer 1112 and second superconducting layer 1116 are patterned superconducting films separated by barrier layer 1114 to create a Josephson junction region. Barrier layer 1114 may be an insulating barrier, a semiconducting barrier, a thin oxide barrier, a weak-link region, a structurally thinned region, or another region through which Josephson coupling can occur. Magnetic-flux input region 1118 indicates that the junction-containing structure may be incorporated into a loop or interferometric device responsive to applied magnetic flux.

Still referring to FIG. 11, the Josephson-junction embodiment may be fabricated using one or more patterned superconducting layers derived from the disclosed Penrose-template process. In one embodiment both superconducting layers are Penrose-pattern-derived films. In another embodiment only one superconducting layer uses the full Penrose-derived architecture while the other is a reference superconducting layer. In another embodiment barrier layer 1114 is formed by interposed dielectric deposition. In another embodiment barrier layer 1114 is formed by local oxidation or thickness-controlled weak-link definition. In another embodiment junction formation is achieved by pattern narrowing or selective material removal.

Still referring to FIG. 11, when the junction embodiment is arranged in a loop structure responsive to magnetic flux, the resulting architecture may function as a SQUID magnetometer or related magnetic-sensing device. In such embodiments magnetic-flux input region 1118 may be part of a pickup loop, sensor loop, or controlled flux-coupling region. The patterned superconducting film can thus be fabricated in reproducible form and integrated into junction-based device topologies.

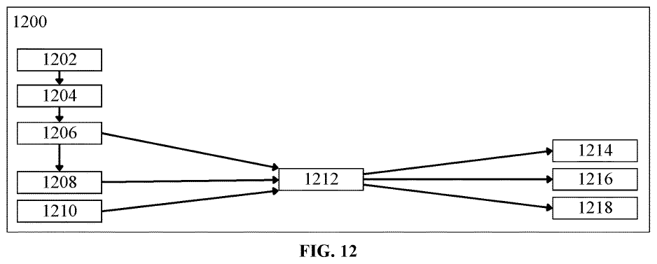

Referring now to FIG. 12, a design, validation, and advanced-device embodiment is shown schematically as design and validation system 1200. Design and validation system 1200 includes processor 1202, memory 1204, mask file 1206, process recipe 1208, non-transitory storage medium 1210, validation workflow 1212, quasicrystalline bulk article 1214, qubit lattice structure 1216, and qualified superconducting article 1218. FIG. 12 illustrates physical material structures, digital manufacturing artifacts, validation pipelines, and advanced embodiments that rely on the same patterned superconducting platform concept.

Still referring to FIG. 12, processor 1202 and memory 1204 may form part of a workstation, design server, fab-control computer, or distributed manufacturing-control environment. Mask file 1206 may store the Penrose geometry, tile-edge scaling, write-field placement, bias corrections, field-stitching management data, template-boundary definitions, device-specific active-region selections, or other layout information needed to generate a lithography-ready pattern. Process recipe 1208 may store deposition settings, anneal parameters, validation thresholds, material-selection options, device-variant settings, scaling information, process sequencing logic, or corrective-action rules. Non-transitory storage medium 1210 may store one or both of mask file 1206 and process recipe 1208 in durable machine-readable form.

Still referring to FIG. 12, a deterministic quasiperiodic fabrication process may benefit from reproducible digital control. Unlike a simple periodic grid, a Penrose-derived pattern may require stored deterministic layout information or generation logic so that multiple fabrication runs, tools, or facilities can reproduce the intended template geometry consistently. In some embodiments processor 1202 executes pattern-generation or pattern-export logic. In some embodiments memory 1204 stores active fabrication files, archived layouts, or prior validated pattern variants. In some embodiments non-transitory storage medium 1210 stores canonical pattern and process data for use across multiple fabrication cycles.

Still referring to FIG. 12, validation workflow 1212 represents a process by which fabricated articles are checked against structural and performance requirements. In one embodiment validation workflow 1212 includes structural verification of quasiperiodic order, template-spacing verification, electrical transition testing, magnetic testing, current-density testing, and reproducibility analysis. In another embodiment validation workflow 1212 includes pass-fail logic and rework logic. In another embodiment validation workflow 1212 is used during development rather than production. In another embodiment validation workflow 1212 is embedded in a manufacturing execution system.

Still referring to FIG. 12, quasicrystalline bulk article 1214 represents a three-dimensional embodiment in which the inventive concept is extended beyond a thin-film surface layer. In such an embodiment a bulk or partially bulk structure may include a quasicrystalline region, a cuprate intergrowth region, a patterned current path, or another three-dimensional superconducting architecture derived from or inspired by the disclosed Penrose-template principles. The invention is not limited to exact duplication of the two-dimensional film process in three dimensions. In some embodiments deterministic quasiperiodic superconducting order is engineered into a thicker or volumetric body, for example to increase current-carrying cross section or to exploit bulk vortex-pinning behavior.

Still referring to FIG. 12, qubit lattice structure 1216 represents an advanced device embodiment in which patterned superconducting films are used to define or support a lattice of qubit-forming structures. In one embodiment qubit lattice structure 1216 includes superconducting islands, junction regions, control lines, readout structures, and associated shielding or support elements arranged with reference to a Penrose-derived geometry. In some embodiments the qubit arrangement is used for a surface-code-like architecture. In some embodiments the superconducting platform is used in a transmon-like implementation. In some embodiments a shielding region or recognition-boundary-related shielding approach is additionally employed.

Still referring to FIG. 12, qualified superconducting article 1218 represents a fabricated article that has passed a selected validation workflow. In some embodiments qualified superconducting article 1218 is accepted for later integration into a tape, cable, magnet, levitation element, Josephson device, SQUID device, qubit structure, interconnect structure, or other downstream system. In some embodiments qualification is tiered, such that different articles are assigned to different use categories depending on measured T_c, J_c, structural order, roughness, or reproducibility. In some embodiments marginal articles may still be used in non-critical device experiments.

With respect to the digital and recipe-storage embodiments more generally, a non-transitory computer-readable medium can store one or more of the following categories of information. A first category includes pattern definitions, such as Penrose layout files, tile-edge scaling data, region-of-interest definitions, or direct-write coordinate sets. A second category includes lithography execution data, such as exposure dose, write order, field management, bias correction, and development settings. A third category includes transfer-process data, such as ion-beam milling depth, milling time, beam settings, and endpoint logic. A fourth category includes deposition data, such as source flux setpoints, substrate temperature, rotation speed, and oxidant flow. A fifth category includes anneal data, such as temperature, time, pressure, and gas composition. A sixth category includes validation data, such as metrology thresholds and acceptance criteria.

With respect to the quasicrystalline bulk embodiment, a three-dimensional article may be formed by stacking, intergrowing, templating, infiltrating, or otherwise producing a bulk body in which deterministic quasiperiodic superconducting order is engineered across a finite thickness rather than only at a surface film. In one embodiment a three-dimensional quasicrystalline scaffold is prepared and then overgrown or infiltrated with a superconducting material. In another embodiment stacked patterned films are used to approximate or realize a volumetric quasicrystalline arrangement. In another embodiment a bulk precursor is machined, cast, sintered, or otherwise shaped and then processed to define a quasicrystalline region.

With respect to the qubit-lattice embodiment, the patterned superconducting platform can be adapted into a superconducting computational or control architecture by defining multiple superconducting islands or regions and coupling them through one or more barrier regions or resonant structures. In one embodiment the quasiperiodic lattice spacing derived from a_phi is used to define relative placement of such islands or coupling structures. In another embodiment the Penrose geometry is used more generally to organize the layout rather than to enforce one exact spacing at every local edge. In another embodiment a shielding region is integrated to improve coherence or reduce parasitic interaction.

With respect to validation generally, a fabricated article may first be checked for template fidelity and film continuity. In a second step the article may be checked for quasiperiodic structural evidence, such as a five-fold diffraction signature or corresponding structural marker. In a third step electrical transition behavior may be measured. In a fourth step magnetic response may be measured. In a fifth step current density may be measured. In a sixth step reproducibility may be evaluated over multiple samples or production runs. This validation sequence may be implemented through validation workflow 1212 and may be adapted to the needs of a given manufacturing environment.

In preferred implementations, the disclosed process is carried out iteratively within a bounded engineering workflow in which one or more of template-transfer depth, lithographic fidelity, growth temperature, source ratio, oxidant composition, anneal temperature, anneal duration, anneal pressure, cooldown conditions, or film thickness are adjusted within disclosed or otherwise conventional process windows while preserving the same underlying Penrose-template architecture. A fabricated article may therefore be accepted, reworked, or reassigned based on structural and superconducting validation outcomes without departing from the disclosed method. This process-window disclosure is intended to make clear that the invention includes not only a single nominal recipe point, but also the controlled fabrication and qualification of articles produced through practical engineering variation around the disclosed quasiperiodic templating framework.

With respect to process flow integration, the same architecture may support local embodiments, remote embodiments, batch embodiments, offline embodiments, online embodiments, and audit embodiments. In a local embodiment the entire process from pattern definition through validation is carried out in one facility. In a remote embodiment mask generation and recipe generation are carried out in one location while physical fabrication is carried out in another. In a batch embodiment multiple wafers or tape segments are processed under one recipe run. In an online embodiment validation data are fed back to controller logic in near real time. In an offline embodiment validation data are reviewed later to refine process recipes.

With respect to the relationship between observation, validation, and control, a diffraction result by itself is a measurement output. When compared against a threshold or decision rule within validation workflow 1212, that output becomes a validation input. When the validation input is then used to release, reject, or modify a recipe for a later batch, the information has moved from observation to control. The same measured information may therefore be used both for human review and for machine-actionable process decisions.

With respect to examples, the following examples further illustrate how the disclosed invention may be made and used. Unless expressly stated as actual measured examples, such examples may be prophetic, partially prophetic, or mixed development examples. The examples are illustrative and non-limiting and do not restrict the scope of the broader disclosure. Certain dimensions, operating values, and processing choices may be adjusted while still remaining within the scope of the invention as disclosed.

In a first example directed to an experimental wafer or test-wafer embodiment, a sapphire substrate is provided and a seed layer of SrTiO3 is deposited over the sapphire substrate. A Penrose-pattern template having tile edge a_phi is defined over the seed layer by lithographic writing and transferred into the seed layer by shallow ion-beam milling. A YBa2Cu3O7-delta film is then deposited over the patterned template by oxide molecular beam epitaxy using source materials corresponding to yttrium, barium, and copper. The film is then annealed in an ozone-containing atmosphere under selected temperature and pressure conditions to promote the desired oxygen state. Structural verification is then performed by diffraction analysis, and electrical and magnetic testing are performed by four-probe and SQUID measurements. In presently preferred embodiments, such an example yields a five-fold quasiperiodic structural signature and a superconducting transition near the elevated temperatures described elsewhere in this disclosure.

In a second example directed to a flexible conductor embodiment, a metallic tape substrate is provided and coated with a buffer or seed architecture capable of receiving a Penrose-pattern transfer. A patterned quasiperiodic template is then formed over a selected tape region by direct-write lithography or by nanoimprint replication from a Penrose-pattern master. A superconducting material layer is deposited over the template and subsequently oxygenated. Stabilizing metal and insulation layers are then added as needed, and the resulting conductor is terminated and assembled into a cable or interconnect segment. Structural and electrical validation are used to determine whether the resulting segment is accepted for use in a cable embodiment, a grid-interconnect embodiment, or a shorter-range interconnect embodiment.

In a third example directed to a magnet embodiment, a validated superconducting conductor derived from the disclosed patterned architecture is wound around a support former to create a coil. The coil is connected through suitable terminals and integrated into a magnetic field-generation system. Depending on the intended application, the resulting magnet may be part of an imaging system, a spectroscopy system, an accelerator component, or an energy-storage system. In some embodiments the magnet is operated at room temperature or elevated temperature without the cryogenic burden associated with conventional superconducting magnets. In other embodiments some thermal stabilization is still provided.

In a fourth example directed to a levitation embodiment, one or more patterned superconducting tiles are mounted on a rigid support or guideway body and positioned relative to an external magnetic source so that a levitation gap is established during operation. The tiles may be arranged in an array, may be electrically isolated or interconnected as needed, and may be environmentally sealed. During operation the superconducting tile or tile array participates in a levitation-supporting magnetic interaction.

In a fifth example directed to a Josephson or SQUID embodiment, a patterned superconducting film is processed to define a first superconducting region, a barrier region, and a second superconducting region so that a Josephson junction is formed. The junction may then be incorporated into a flux-sensitive loop, a logic element, a switching element, or a magnetic-sensing structure. In some embodiments the barrier is created by interposed dielectric deposition. In some embodiments the barrier is created by controlled oxidation or local narrowing. In some embodiments multiple junctions are integrated into a loop to create a SQUID-like device.

In a sixth example directed to a qubit-lattice embodiment, a patterned superconducting film is used as a platform for defining superconducting islands, coupling regions, control lines, and readout features arranged according to a Penrose-derived layout. Device-level features are then formed by lithography, etch, deposition, or combinations thereof. The resulting structure may be incorporated into a surface-code-like or transmon-like system. In some embodiments a shielding region is also included.

With respect to manufacturing robustness, multiple implementations may be used for the same core architecture. In one embodiment the preferred YBCO system is formed on sapphire with an SrTiO3 seed layer and direct-write e-beam patterning. In another embodiment a different superconducting chemistry is used on an alternative substrate while retaining the Penrose-template concept. In another embodiment direct-write lithography is replaced by nanoimprint replication for higher-throughput fabrication. In another embodiment selected validated device classes are emphasized for a given production flow. In another embodiment the article is operated at temperatures lower than the most aggressive room-temperature target while still benefiting from the templated quasiperiodic architecture.

A flexible tape embodiment may include insulation and terminals, a magnet embodiment may include a support former and power interface, and a junction embodiment may include a barrier layer and flux-input region. These later-added components do not redefine the underlying patterned superconducting article, but instead represent downstream uses of that article in different device contexts.

Certain features are presently preferred but are not mandatory in all embodiments. By way of example, the exact a_phi relationship, the use of YBa2Cu3O7-delta, the use of sapphire, the use of SrTiO3, the use of oxide molecular beam epitaxy, the use of ozone annealing, and the use of room-temperature operation are preferred in certain embodiments but are not required in every implementation. Across these embodiments, the fabrication of a superconducting article using a deterministic quasiperiodic template, particularly a Penrose-derived template, remains central.

By way of further example, some embodiments may exhibit superconducting transition behavior, magnetic response, or current-carrying performance that is useful yet lower than the highest presently preferred benchmark values described herein. Such embodiments remain within the invention where they are produced through the disclosed deterministic quasiperiodic templating architecture and exhibit one or more structural, electrical, or magnetic signatures consistent with the intended patterned superconducting article. Accordingly, room-temperature and above-room-temperature embodiments are presently preferred in certain implementations, but lower-temperature superconducting embodiments produced by the same Penrose-template fabrication framework are also expressly contemplated and supported.

Controller, memory, recipe, and validation embodiments may store both a historical process record and a current-use record. A historical process record can capture what was done to a given sample or lot. A current-use record can capture whether that sample or lot is presently qualified for a given application. Process history alone does not determine whether an article is released for downstream use. Release status may depend on the validation outcomes described above. The deterministic nature of the patterning workflow provides a foundation for lot-to-lot consistency that is not available in a merely roughened or randomly disordered growth surface. Because the Penrose geometry is defined by stored digital information or deterministic generation logic, multiple samples can be fabricated from the same underlying pattern specification. Because later process stages can also be recipe-controlled and validation-controlled, the system supports reproducible fabrication and reproducible acceptance decisions. This reproducibility is a practical technical effect of the disclosed architecture and is separate from any particular explanatory theory of superconducting behavior.

In embodiments in which process control is performed in a closed loop, the controller and memory elements described earlier may compare measured structural or superconducting outputs against one or more thresholds and then alter a subsequent fabrication run based on the comparison. By way of example, if a measured transition temperature falls below a selected threshold, a later run may be assigned a modified oxygenation schedule, modified deposition rate, modified pattern-transfer depth, modified source-ratio calibration, or modified growth temperature. If a structural characterization result indicates that quasiperiodic order is degraded in edge regions, a later run may use a revised active-area definition or revised write-field management strategy.

In embodiments in which process control is performed in an open-loop or recipe-driven fashion, the controller and memory elements may simply execute a stored sequence without dynamic mid-run adaptation. In such embodiments deterministic execution of a stored Penrose-pattern and stored process recipe can provide reproducibility relative to ad hoc approaches. In other embodiments an initially fixed recipe may later be revised between runs after review of accumulated structural, electrical, magnetic, or dimensional data.

One or more fabrication tools may require calibration of pattern scale, beam position, substrate temperature, flux rate, oxygenation pressure, metrology offset, or other process parameters. Such calibration may be performed before a production run, between runs, or during commissioning of a tool. In some embodiments calibration data are stored with process recipe data so that a particular lot can be traced to the calibration state used. In some embodiments pattern-scale calibration is particularly important because the disclosed architecture uses a tile edge intended to correspond to a concrete physical dimension. Digital pattern definitions may thereby be translated into physical template dimensions through calibrated write-tool or replication-tool behavior.

A run or article may fail for numerous reasons without departing from the scope of the invention. By way of non-limiting example, pattern-transfer fidelity may be insufficient, superconducting-film continuity may be compromised, oxygenation may be incomplete, structural ordering may be below threshold, electrical transition behavior may be broadened or shifted, magnetic response may be weak, or current density may be inadequate for a target use. In one embodiment a failed article is discarded. In another embodiment a failed article is reworked, such as by additional anneal treatment or secondary validation. In another embodiment a failed article is reassigned to a less demanding use category.

A measured output such as a diffraction pattern, transition curve, Meissner response, or current-density value constitutes detection or observation. A subsequent comparison of that measured output against an acceptance criterion constitutes evaluation. A release, rejection, rework, reassignment, or recipe-change action based on that evaluation constitutes decision and control.

A structural or electrical test result can verify the presence of a feature or quantify a performance metric without itself deciding whether the article is acceptable for a given business, regulatory, or deployment purpose. An acceptance rule, in contrast, may incorporate policy choices in addition to measured facts. For example, an article may be technically superconducting and still be withheld from a medical magnet application because its lot reproducibility is below a conservative release criterion.

The disclosed systems may produce both human-readable outputs and machine-actionable outputs. A plot, table, report, or engineering note may be human-readable. A parameter-update command, release flag, reject code, or tool-execution file may be machine-actionable. In one embodiment the same validation workflow produces both a human-readable qualification report and a machine-actionable disposition code. In some embodiments the disclosed architecture supports operational control of fabrication or release decisions based on the information produced.

Digital pattern files and process recipes may undergo revisions of more than one type. A semantic change is a change that alters actual fabrication content, such as changing tile edge, active-area layout, transfer depth, source ratio, growth temperature, or anneal settings. A presentation-only change is a change that affects display format, annotation style, labeling convention, or file organization without altering the actual content used for fabrication. The systems and methods described herein may track one or both types of change.

A record may be stored without being validated, and an article may be validated based on stored records and measured data without all stored records themselves being independently revalidated. For example, a mask file may be stored as a canonical template, while a produced wafer may be validated by metrology and electrical testing. The existence of a file in storage does not alone establish that the article fabricated from it is acceptable. Conversely, an article may pass validation even if the supporting digital archive is later reorganized.

A historical record may indicate that a particular pattern file, recipe, tool set, and calibration state were used to fabricate an article. A current-use record may indicate whether that article is currently approved for tape integration, magnet integration, junction fabrication, or another downstream use. The current-use record may change over time even when the historical record remains fixed. This may be useful in embodiments involving requalification, aging studies, or application-specific release criteria.

The flexible conductor architecture described with respect to FIG. 10 may be formed into single-conductor cables, multi-conductor cables, laminated bus structures, braid-supported conductors, wrapped tape assemblies, coaxial structures, cryostat-free conductor packages, or hybrid assemblies combining superconducting segments with normal-metal segments. In some embodiments conductor terminals are formed by soldering, diffusion bonding, clamping, metallization, or deposited contact structures. In some embodiments insulation is selected for high-voltage operation. In some embodiments the patterned superconducting film occupies only selected portions of the overall conductor path.

A plurality of tape-based conductors fabricated according to the present disclosure may be combined into a cable assembly sized for utility or sub-utility scale current transport. In one embodiment multiple flexible superconducting tape segments are stacked or helically arranged and enclosed within a protective outer structure. In another embodiment the conductor path is segmented for fault isolation or modular replacement. In another embodiment terminals and connector hardware are configured for installation between substations or other grid nodes. The patterned superconducting platform can thereby be fabricated in tape form and integrated into a practical current-transport structure.

Patterned superconducting conductors can also be fabricated in shorter lengths, finer widths, or board-level or rack-level configurations suitable for lower-loss interconnect pathways. In one embodiment a patterned superconducting tape is used as a high-current inter-rack bus. In another embodiment narrower patterned conductors are used as board-to-board or module-to-module interconnect structures. In another embodiment the patterned superconducting film is integrated onto a support substrate or carrier structure adapted for computing infrastructure.

An MRI-oriented implementation may use superconducting conductor segments wound into a bore-defining coil system configured to create a region of magnetic field suitable for imaging. An NMR-oriented implementation may instead prioritize field stability and analytical sample access. A particle-accelerator implementation may use elongated windings and support structures to create steering or focusing fields in a beamline environment. An SMES-oriented implementation may use a persistent-current storage loop or a controlled-discharge arrangement connected to power electronics. In each case the patterned superconducting platform may be used in a coil-based device while exact packaging and field specifications are selected according to the particular application.

In magnetic levitation embodiments, the superconducting elements may be tiled, segmented, or arrayed along a guideway or support body. In one embodiment each tile is individually fabricated and then mounted onto a structural beam or panel. In another embodiment a larger continuous support sheet carries multiple patterned superconducting regions. In some embodiments a protective overlayer is added to resist environmental wear. In some embodiments the superconducting tiles cooperate with permanent magnets. In other embodiments they cooperate with electromagnets. In still other embodiments the levitation-supporting behavior is used not for transport but for low-friction support, isolation, or bearing applications.

In Josephson-junction embodiments, the barrier region may be defined by one or more techniques selected according to the intended junction behavior. In one approach a thin dielectric or insulating film is deposited between two superconducting layers. In another approach a locally thinned or narrowed superconducting bridge functions as a weak link. In another approach a patterned oxidation step forms a tunnel barrier. In another approach the barrier includes a semiconducting or mixed-composition interlayer. The disclosed embodiments therefore include a family of junction-forming techniques anchored to the same patterned superconducting platform article.

In SQUID embodiments, one or more Josephson junctions may be incorporated into a loop body that responds to magnetic flux passing through or coupled into the loop area. In one embodiment the loop is formed lithographically from the patterned superconducting film. In another embodiment separate superconducting regions are interconnected to define the loop. In another embodiment the flux-input region is optimized for sensitivity to an external field source. In some embodiments the SQUID device is used as a sensor. In other embodiments related loop-and-junction structures are used as switching or logic elements.

In qubit embodiments, a qubit lattice structure may include superconducting islands, junctions, capacitive regions, inductive regions, control traces, readout resonators, shielding regions, and support substrates. In one embodiment the layout follows a Penrose-derived organization to create a quasiperiodic qubit array. In another embodiment the Penrose-derived superconducting film is used as the base material while selected local device features are patterned according to another device-specific rule set. In either case a deterministic quasiperiodic superconducting platform can underlie a quantum-device-oriented architecture. Such embodiments may be prophetic in certain implementations, but are described with structural and procedural detail sufficient to illustrate fabrication and use.

A volumetric superconducting structure may be formed by stacking multiple patterned films, by growing superconducting material into a three-dimensional quasicrystalline scaffold, by assembling modular superconducting elements into a bulk body, or by producing an intergrowth architecture that extends quasiperiodic ordering beyond a single surface plane. In one embodiment a plurality of patterned layers are aligned and bonded. In another embodiment a quasicrystalline support body is infiltrated. In another embodiment a volumetric architecture is used to increase current capacity or alter vortex behavior.

The processes described herein may be implemented in research-scale facilities, pilot-scale facilities, or production-scale facilities. In a research-scale facility direct-write patterning and small-area coupons may be used. In a pilot-scale facility larger-area wafers or tape sections and more standardized validation may be employed. In a production-scale facility replicated patterning, automated recipe handling, and tiered validation may be emphasized.

One or more layers in the disclosed stack may be substituted so long as the functional architecture is preserved. For example, a preferred SrTiO3 seed layer may be replaced by another oxide or buffer architecture. A preferred sapphire substrate may be replaced by another rigid or flexible substrate. A preferred YBa2Cu3O7-delta film may be replaced by another superconducting chemistry. A preferred ozone anneal may be replaced by another oxygenation treatment.

The Penrose-derived geometry remains central, but equivalent deterministic quasiperiodic implementations that preserve the intended templating function may also be used. In some embodiments the exact finite clip of the Penrose domain is changed. In some embodiments the pattern is mirrored, rotated, scaled, or trimmed for fit to a device footprint. In some embodiments local inactive regions are omitted from patterning while active regions preserve full quasiperiodic definition. In some embodiments a quasi-equivalent deterministic aperiodic pattern having the same intended growth-guiding function may be used.

Some embodiments follow the preferred order of substrate preparation, seed-layer deposition, quasiperiodic patterning, pattern transfer, superconducting deposition, oxygenation, and validation. Other embodiments may combine or reorder selected compatible operations. For example, certain pre-cleaning, pre-bake, or conditioning steps may be inserted. Certain metrology operations may occur before and after transfer. Certain partial validation steps may occur before full oxygenation. The invention is not limited to one strict sequence except where sequence is technically necessary for a given embodiment.

Multiple articles may be fabricated according to a common pattern and recipe and then screened by validation. In one embodiment articles are processed together on a single wafer. In another embodiment multiple wafers are processed in one lot. In another embodiment multiple tape segments are processed in a semi-continuous line. In each case some articles may qualify for one downstream use while others qualify for another or fail qualification entirely.

An online embodiment may use in situ monitoring such as RHEED or immediate post-process metrology to influence actions before the article leaves the tool chain. An offline embodiment may collect measurements after fabrication and then use those measurements later to update recipes, qualification rules, or application assignments. Both forms preserve the architecture of deterministic template formation followed by superconducting-film fabrication and validation. Pattern generation, deposition, annealing, validation, and device integration may all occur in a single facility or may be distributed across multiple facilities. For example, a centralized design system may generate mask files, a specialized fabrication facility may form patterned superconducting wafers, and a downstream device facility may integrate qualified articles into magnets, conductors, or junction devices.

The term “patterned quasiperiodic template” refers to a physically realized structure at or on a growth-supporting layer and does not refer merely to an image, drawing, or abstract mathematical description. The term “superconducting article” refers to a physical platform that may be an intermediate structure suitable for later device integration or a more fully integrated structure. The term “validation” refers to comparison of observed characteristics against one or more criteria and is distinct from observation alone.

The tile edge is a written dimension. The template is physically transferred. The superconducting film is deposited over the template. The oxygenation stage is separately performed. The resulting article is structurally and electrically validated. Device embodiments are built from the article. Digital embodiments store pattern and process content that can be used to reproduce the article. A deterministic Penrose-derived template is physically imposed at a specific scale and then used to guide superconducting-film formation within a fabrication and validation architecture. The disclosed technical effects are linked to that architecture.

When this disclosure states that a feature “may” be used, that wording preserves alternative embodiments and does not suggest that the described feature lacks technical relevance. When this disclosure states that a feature is “preferred” or “presently preferred,” that wording identifies a favored implementation without restricting broader embodiments. The examples, equations, materials, dimensions, and downstream device classes described herein are illustrative and non-limiting.

The term “template fidelity” refers to the degree to which the physically realized quasiperiodic template corresponds to the intended deterministic pattern definition stored in the mask, recipe, or generation logic. Template fidelity may be assessed by dimensional metrology, imaging, diffraction-compatible structural assessment, or comparison of measured surface features against intended pattern data. The term “qualification” refers to a determination that a fabricated article satisfies one or more selected criteria for a selected downstream use. Qualification may be binary or tiered. The term “rework” refers to one or more additional process or validation actions performed after an initial result has been obtained. The term “qualified superconducting article” refers to a fabricated article that has been evaluated and accepted for at least one specified use category.

All numerical values stated in this disclosure are illustrative of presently preferred embodiments unless the context clearly requires otherwise. When a numerical value is given, embodiments may include values exactly at that number, approximately at that number, within ordinary manufacturing or measurement tolerance of that number, or within a range that a person of ordinary skill in the relevant art would recognize as functionally consistent with the disclosed purpose. The use of one preferred value does not exclude neighboring values, scaled values, or process-specific adjustments that preserve the disclosed architecture and intended function. Words such as over, under, above, below, upper, lower, top, bottom, within, on, at, adjacent, coupled, connected, supported, formed over, formed on, disposed over, and similar terms are used for convenience with reference to the figures and do not require a specific gravitational orientation unless expressly stated. A layer described as being formed over another layer may be directly on that layer or may be indirectly supported by one or more intermediate layers, structures, or interfaces. Likewise, a feature described as being coupled or connected may be directly coupled or connected or indirectly coupled or connected through one or more intervening elements.

A named material such as YBa2Cu3O7-delta, SrTiO3, sapphire, BSCCO, a nickelate, or an iron-based superconductor includes exact stoichiometric forms, near-stoichiometric forms, process-compatible variants, doped forms, substituted forms, oxygen-adjusted forms, phase-compatible forms, and other materially related implementations suitable for the disclosed function unless the context clearly indicates a narrower meaning. The naming of one preferred material family does not exclude related materials capable of participating in the same templated quasiperiodic superconducting architecture.

Equations appearing in this specification are included to support understanding, to define presently preferred design relationships, and to document one preferred explanatory or selection basis for particular embodiments. Except where an equation is expressly incorporated into a claimed limitation, embodiments need not satisfy a given equation with mathematical exactness. This is especially true for embodiments involving manufacturing tolerances, alternative superconducting chemistries, scale changes, or different process implementations.

The present disclosure distinguishes between the physical fabrication and article description on one hand and a non-limiting explanatory framework on the other. The described quasiperiodic, phi-related, and J-cost-related framework may be useful for understanding and selecting preferred embodiments. However, the invention is not limited by any particular scientific consensus regarding the underlying cause of the observed or predicted superconducting behavior.

Features described in connection with one embodiment may be used with features described in connection with another embodiment unless the combination is technically incompatible. By way of example, a flexible conductor embodiment may use a direct-write patterning route or a nanoimprint route. A Josephson-junction embodiment may be formed from a YBCO-based platform or another superconducting chemistry. A validation workflow described in connection with wafer qualification may also be applied to tape segments or junction precursors. A digital pattern-storage embodiment may be used in connection with rigid wafers, flexible tapes, bulk structures, or advanced-device embodiments.

One or more steps of the disclosed method may be carried out by separate entities, tools, or facilities while still participating in one overall inventive process. For example, a first facility may generate or store mask data, a second facility may form the patterned template, a third facility may perform superconducting deposition and oxygenation, and a fourth facility may perform validation or device integration. Such distributed practice does not alter the disclosed deterministic quasiperiodic fabrication architecture.

Each fabricated article, wafer, tile, tape segment, coil precursor, junction precursor, or other superconducting platform body may be associated with an identifier, recipe state, validation state, lot identifier, or application assignment. Such tracking may be stored in digital form and may be used for traceability, quality assurance, release control, or later audit. In embodiments involving multiple output classes, a first article may be accepted for a magnet embodiment while a second article from the same batch may be accepted only for a less demanding test or interconnect embodiment.

Processor-based systems described herein may execute software, firmware, hardware logic, or combinations thereof. Memory and storage may include volatile memory, non-volatile memory, local storage, remote storage, or distributed storage. Pattern-generation logic may be stored as executable instructions, symbolic pattern data, geometric constructs, lookup tables, rule sets, or a combination thereof, so long as the machine-readable information can be used to create or control the disclosed patterned superconducting fabrication process.

Structural and dimensional measurements may be carried out using one or more of microscopy, diffraction, scanning probe techniques, profilometry, electrical probing, magnetic testing, optical inspection, or related metrology tools. Every article need not be subjected to every possible metrology mode. In some embodiments a reduced screening set is used for routine production and a deeper screening set is used for qualification lots or dispute resolution. In some embodiments the metrology sequence is adapted according to the intended downstream use, with more demanding applications using stricter or more extensive validation gates.

An article may be accepted based on one threshold, multiple thresholds, weighted criteria, hierarchical rules, or staged qualification logic. In one embodiment an article is first required to pass a structural threshold, then an electrical threshold, then a magnetic threshold, and optionally a reproducibility threshold. In another embodiment different downstream applications use different qualification pathways. For example, a magnet embodiment may emphasize current-carrying performance and field stability, whereas a junction embodiment may emphasize film continuity and junction-forming suitability, and a levitation embodiment may emphasize structural continuity and magnetic response.

The deterministic nature of the pattern geometry means that an article fabricated at one scale can often be conceptually translated to another scale so long as the functionally relevant pattern, deposition, and validation relationships are preserved. In some embodiments this means moving from a small coupon to a larger wafer. In some embodiments it means moving from a single patterned tile to an array. In some embodiments it means translating from direct-write prototyping to replicated manufacturing.

Phrases such as conforming to the template, influenced by the template, guided by the template, templated by the pattern, or exhibiting a quasiperiodic growth architecture capture different degrees and modes of interaction between the physically realized template and the deposited superconducting material. These phrases do not require one rigid microscopic mechanism in every embodiment. Instead, they reflect that the physical template is part of the causal fabrication architecture that leads to the resulting superconducting article.

Certain embodiments may require additional protections or controls depending on the selected material system. By way of example, Hg-based implementations may require enhanced toxic-material handling. Ozone-based anneal systems may require ozone-compatible gas handling and exhaust treatment. High-current conductor embodiments may require appropriate electrical insulation and enclosure design. Device-level medical or transport uses may require compliance with separate regulatory standards. Such additional implementation details may be incorporated as needed according to the chosen deployment context.

The figures and examples are illustrative and are not intended to restrict the invention to the exact combinations shown. A particular figure may schematically combine functions or structures that are separated in an actual implementation, and a particular example may omit components or processing variations present in another embodiment. Conversely, features shown or described separately may be combined in a single physical system where technically compatible.

Singular terms may include the plural and plural terms may include the singular where the context permits. Thus, for example, a substrate may include multiple substrate portions, a seed layer may include multiple sublayers, a superconducting film may include one or more superconducting regions, and a mask file may include one or more files or data structures. Likewise, references to a controller, memory, or storage medium may include multiple coordinated controllers, memories, or storage media.

Terms such as comprising, including, having, carrying, storing, defining, supporting, and the like are intended in an inclusive sense unless the context clearly requires otherwise. Embodiments may therefore include additional unrecited structures, process steps, control logic, packaging, or validation operations beyond those expressly enumerated in a given example.

The resulting superconducting platform may be described in different but compatible ways depending on context. In one characterization it is a patterned superconducting article comprising a substrate-supported quasiperiodic template and a superconducting film. In another characterization it is a templated superconducting heterostructure. In another characterization it is a Penrose-pattern-derived superconducting film stack. In another characterization it is a superconducting platform article for later device integration.

The disclosed fabrication route may be described as a method of making a superconducting article, a method of forming a patterned quasiperiodic template and overgrowing a superconducting film thereon, a method of producing a room-temperature or elevated-temperature superconducting platform, a method of validating a patterned superconducting article, or a method of storing and executing pattern and recipe data for such fabrication.

The technology may also be described as a fabrication system, a validation system, a design-and-recipe system, a distributed manufacturing system, or an integrated patterned-superconductor production environment. Such system-level characterizations correspond to the disclosed processor, memory, mask data, recipe data, fabrication tools, oxygenation tools, and validation pathways.

The examples and embodiments described herein are illustrative and not exhaustive. A person of ordinary skill in the relevant art, having the benefit of the present disclosure, will recognize that substitutions, modifications, rearrangements, and process-specific adaptations can be made while preserving the inventive concept. Such changes may involve tool choice, layer order, exact materials, exact operating ranges, device packaging, validation thresholds, or digital-control architecture. Changes that preserve the disclosed patterned quasiperiodic superconducting fabrication and article framework remain within the scope of the invention.

A patterned superconducting article fabricated according to the present disclosure may be incorporated into a single downstream system or into multiple different downstream systems without requiring alteration of the underlying Penrose-derived template concept. Thus, a film stack initially fabricated as a validated platform article may later be diced, segmented, wound, mounted, contacted, encapsulated, interconnected, or otherwise configured according to the requirements of a conductor embodiment, magnet embodiment, levitation embodiment, junction embodiment, qubit embodiment, or other selected implementation.

One or more interfaces within the disclosed stack may be modified to improve adhesion, lattice accommodation, oxygen transport, defect control, chemical compatibility, or long-term stability. In some embodiments an adhesion-promoting layer is included between a substrate and a seed layer. In some embodiments an interfacial smoothing treatment is performed before Penrose-pattern transfer. In some embodiments a barrier layer is introduced to reduce diffusion of unwanted species. In some embodiments one or more interfaces are annealed, conditioned, plasma treated, or chemically cleaned before subsequent processing.

The substrate or seed-layer surface may be cleaned, planarized, baked, outgassed, passivated, activated, or otherwise conditioned before pattern definition or superconducting deposition. In one embodiment a substrate is solvent cleaned and thermally baked before seed-layer deposition. In another embodiment a seed layer is surface conditioned before resist application. In another embodiment an in situ thermal treatment is used to desorb contaminants before oxide growth. Such surface-preparation operations may improve pattern fidelity, film continuity, and reproducibility.

Humidity, particulate loading, temperature stability, vibration, electromagnetic interference, gas purity, and vacuum integrity may each affect the resulting patterned superconducting article. In some embodiments the pattern-definition process is carried out in a controlled cleanroom environment. In some embodiments deposition materials are purified or monitored to limit contamination. In some embodiments anneal gases are filtered or generated immediately before use. In some embodiments metrology is conducted under conditions selected to reduce noise or drift.

A partly fabricated stack such as a patterned seed-layer precursor or an as-deposited superconducting film may be stored temporarily before a later process stage. In some embodiments such storage occurs under dry gas, vacuum, refrigeration, or contamination-controlled conditions. In some embodiments handling carriers, cassettes, fixtures, or sealing enclosures are used to protect the patterned surface from damage or contamination. In some embodiments a temporary storage state is recorded in memory together with the associated lot or article identifier.

An article initially qualified for a given downstream use may later be remeasured after storage, transport, environmental exposure, partial integration, or extended operation. In one embodiment a requalification workflow includes repeat electrical testing. In another embodiment requalification includes magnetic or structural retesting. In another embodiment requalification includes only a subset of the original validation sequence where prior data and application risk justify abbreviated retesting. Thus, qualification status may be updated over time without changing the original article identity or fabrication history.

An article that has degraded, fallen below a threshold, or been mechanically altered may in some embodiments be reannealed, recoated, repatterned in part, recontacted, repackaged, or reassigned. In one embodiment a conductor article receives a secondary oxygenation treatment. In another embodiment damaged terminal structures are replaced while the patterned superconducting region is retained. In another embodiment a junction precursor is repatterned locally after an initial failure analysis. These options may be selected according to the nature of the observed deficiency and the intended downstream application.

A finished or intermediate superconducting article may be enclosed within a housing, sheath, enclosure, laminate, or encapsulation selected for the intended environment. In one embodiment a flexible conductor is jacketed for electrical isolation and mechanical protection. In another embodiment a rigid tile is encapsulated for levitation or guideway service. In another embodiment a junction device is packaged in a shielded enclosure. In another embodiment a magnet-related conductor is impregnated, wrapped, potted, or otherwise secured in a coil assembly. The packaging chosen for a particular device does not alter the underlying patterned superconducting article from which the device is derived.

One or more conductive terminals, pads, tabs, leads, buses, vias, plated regions, bonded contacts, or deposited metallization regions may be formed on or coupled to the patterned superconducting article. In one embodiment a conductor terminal is formed at an end region of a tape article. In another embodiment junction contacts are formed on opposing superconducting regions. In another embodiment a readout or control structure is coupled to a qubit-related embodiment. Contact materials and geometries may be chosen according to conductivity, compatibility, thermal expansion, mechanical robustness, and downstream assembly requirements.

A superconducting article may be reinforced or carried by frames, formers, beams, carriers, laminates, stiffeners, reels, spools, or modular support bodies. In one embodiment a magnet conductor is supported by a winding former. In another embodiment a levitation tile is mounted on a structural beam. In another embodiment a patterned wafer is supported by a carrier during dicing or device integration. Mechanical support elements may be permanent or temporary and may be selected according to load, environment, thermal cycling, and assembly workflow.

A larger device may include multiple patterned superconducting articles operating in parallel, in series, in distributed zones, or in replaceable modules. In one embodiment a cable includes multiple parallel tape conductors. In another embodiment a levitation structure includes a replaceable tile array. In another embodiment a magnet includes multiple coil modules. In another embodiment a distributed sensing or qubit structure includes multiple patterned regions formed on one or more substrates. Modular construction may facilitate qualification, service, fault isolation, or staged manufacturing.

A downstream device incorporating the patterned superconducting article may include one or more sensors for temperature, current, voltage, magnetic field, strain, vibration, or environmental condition. In one embodiment operational sensor data are compared against stored thresholds associated with the originally qualified article class. In another embodiment operational data are logged for aging analysis or requalification planning. In another embodiment protective action is taken if an operating condition departs from an allowed range. Such operational monitoring may be integrated with the same digital-control environment used during fabrication and validation.

1. A method of forming a superconducting article, the method comprising: providing a substrate; forming a seed layer over the substrate; patterning the seed layer to define a deterministic quasiperiodic template comprising a Penrose tiling having a tile edge a_phi, wherein a_phi=6phi*a_B, where phi=(1+sqrt(5))/2 and a_B is the Bohr radius; depositing a superconducting material over the deterministic quasiperiodic template; and oxygenating the deposited superconducting material to form a superconducting film that exhibits five-fold quasiperiodic diffraction symmetry over at least a selected region.

2. The method of claim 1, wherein the substrate comprises sapphire.

3. The method of claim 1, wherein the seed layer comprises SrTiO3.

4. The method of claim 1, wherein patterning the seed layer comprises lithographically writing the Penrose tiling into a resist over the seed layer and transferring the Penrose tiling into the seed layer.

5. The method of claim 4, wherein lithographically writing the Penrose tiling comprises electron-beam lithography.

6. The method of claim 4, wherein transferring the Penrose tiling into the seed layer comprises ion-beam milling.

7. The method of claim 1, wherein depositing the superconducting material comprises oxide molecular beam epitaxy at approximately 720 C.

8. The method of claim 1, wherein the superconducting material comprises YBa2Cu3O7-delta.

9. The method of claim 1, wherein oxygenating the deposited superconducting material comprises annealing at approximately 300 C for approximately 3 minutes at approximately 200 mbar ozone pressure.

10. The method of claim 1, wherein the superconducting film exhibits zero-resistance critical temperature T_c of at least 350 K at ambient pressure.

11. The method of claim 1, wherein the tile edge a_phi is derived from the stated RS relationships and is not empirically selected from a set of alternatives or fitted to measured data.

12. The method of claim 1, wherein transferring the Penrose tiling into the seed layer comprises forming relief features to a depth on the order of a few nanometers.

13. The method of claim 1, further comprising validating the superconducting article by diffraction analysis and four-probe electrical testing.

14. A superconducting article comprising: a substrate; a seed layer disposed over the substrate; a deterministic quasiperiodic template defined at or within the seed layer, the deterministic quasiperiodic template comprising a Penrose tiling having a tile edge a_phi, wherein a_phi=6phi*a_B, where phi=(1+sqrt(5))/2 and a_B is the Bohr radius; and a superconducting film disposed over the deterministic quasiperiodic template and exhibiting five-fold quasiperiodic diffraction symmetry.

15. The superconducting article of claim 14, wherein the substrate comprises sapphire.

16. The superconducting article of claim 14, wherein the superconducting film exhibits a Meissner fraction greater than about 95 percent at 350 K.

17. The superconducting article of claim 14, wherein the superconducting film exhibits critical current density of about 3×10\hat{ }6 A/cm\hat{ }2 at 300 K.

18. The superconducting article of claim 14, wherein the deterministic quasiperiodic template comprises recessed template features and raised template features formed in the seed layer.

19. The superconducting article of claim 14, wherein the tile edge a_phi is approximately 5.15 Angstrom or approximately 0.515 nm.

20. The superconducting article of claim 14, wherein the superconducting film exhibits zero-resistance critical temperature T_c of at least 400 K at ambient pressure.
